(19) United States
(12) Patent Application Publication
(10) Pub. No.: US 2024/0032281 A1
(43) Pub. Date: Jan. 25, 2024

(54) MEMORY CELL STRUCTURE

(71) Applicant: Invention And Collaboration Laboratory Pte. Ltd., Singapore (SG)

(72) Inventors: Chao-Chun Lu, Taipei City (TW); Ming-Hong Kuo, Hsinchu (TW); Chun-Nan Lu, Hsinchu (TW)

(73) Assignee: Invention And Collaboration Laboratory Pte. Ltd., Singapore (SG)

(21) Appl. No.: 18/223,560

(22) Filed: Jul. 19, 2023

Related U.S. Application Data
(60) Provisional application No. 63/393,317, filed on Jul. 29, 2022.
(60) Provisional application No. 63/390,676, filed on Jul. 20, 2022.
(60) Provisional application No. 63/390,680, filed on Jul. 20, 2022.
(60) Provisional application No. 63/390,682, filed on Jul. 20, 2022.

(51) Int. Cl. H10B 12/00

(52) U.S. Cl. CPC H10B 12/373; H10B 12/482

(57) ABSTRACT

A memory cell structure includes a silicon substrate, a transistor, and a capacitor. The silicon substrate has a silicon surface. The transistor is coupled to the silicon surface, the transistor includes a gate structure, a first conductive region, and a second conductive region. The capacitor has a signal electrode and a counter electrode, the capacitor is over the transistor, and the signal electrode is electrically coupled to the second conductive region of the transistor and isolated from the first conductive region of the transistor. The counter electrode includes a plurality of sub-electrodes electrically connected with each other.

### CROSS REFERENCE TO RELATED APPLICATIONS

This application claims the benefit of U.S. Provisional Application No. 63/393,317, filed on Jul. 29, 2022. Further, this application claims the benefit of U.S. Provisional Application No. 63/390,676, filed on Jul. 20, 2022. Further, this application claims the benefit of U.S. Provisional Application No. 63/390,680, filed on Jul. 20, 2022. Further, this application claims the benefit of U.S. Provisional Application No. 63/390,682, filed on Jul. 20, 2022. The contents of these applications are incorporated herein by reference.

### BACKGROUND OF THE INVENTION

### 1. Field of the Invention

The present invention relates to a memory cell structure, and particularly to a memory cell structure which not only compacts a size of a DRAM cell but also enhances a signal-to-noise ratio during the DRAM cell operation.

### 2. Description of the Prior Art

One of the most important volatile-memory integrated circuits is the DRAM (Dynamic Random Access Memory) using the 1T1C memory cell, which not only provides the best cost-performance function as main memory and/or buffer memory for computing and communication applications but also has acted as the best driver for technology scaling-down to sustain the Moore's Law from minimum feature size on the silicon from several micrometers down to twenty nanometers or so. Recently the Logic Technology which continues using embedded SRAM (Static Random Access Memory) as its scaling-down driver reveals the claim of achieving the most advanced technology-node near 3 nanometers into manufacturing. In comparison, the best claim of the technology-node of DRAM is still above 10 to 12 nanometers. The major problem is that the 1T1C Cell structure is very hard to be further scaled down by even using very aggressive design rules, scaled access transistor (i.e. 1T) design and three-dimensional storage capacitor (i.e. 1C) such as a stacked capacitor over part of the transistor and isolation areas or a very deep trench capacitor.

The difficulties for the 1T1C DRAM Cell are elaborated here though they are well-known problems even under huge financial and research and development investments on technology, design and equipment. To give a few examples of the difficulties: (1) the access transistor structure suffers unavoidable but more serious current leakage problem to degrade the 1T1C memory Cell storage functions such as reducing the DRAM refresh time; (2) the complexities of arranging the word lines, bit lines and storage capacitors on their geometric and topographic structures and their connections to the gate, source and drain regions of the access transistors are getting much worse for scaling down; (3) trench capacitor suffers too large aspect ratio of the depth versus opening size and is almost halted after 50 nm technology node; (4) the stacked capacitor suffers the worsen topography and there is almost no space for the contact spaces between the storage electrode to the source region of the access transistor after twisting the active region from 20 degree to over 50 degree, etc. In addition, the allowable space for the bit line contact to the drain region of the access transistor is getting so small but a self-aligned feature must still be struggled to maintain; (5) the worsen leakage current problem demands enhancing the storage capacitance and keeping increasing the height of the capacitor to have a larger capacitance area unless a much High-K dielectric insulator material for the storage capacitance can be discovered; (6) without technology breakthroughs of solving the above difficulties all increasing demands on better reliability, quality and resilience of DRAM chips under increasingly demanding higher density/capacity and performance are getting harder to be met, and so on.

Therefore, how to solve the above-mentioned well-known problems has become an important issue of a designer of the 1T1C DRAM Cell.

### SUMMARY OF THE INVENTION

An embodiment of the present invention provides a memory cell structure. The memory cell structure includes a silicon substrate, a transistor, and a capacitor. The silicon substrate has a silicon surface. The transistor is coupled to the silicon surface, the transistor includes a gate structure, a first conductive region, and a second conductive region. The capacitor has a signal electrode and a counter electrode, the capacitor is over the transistor, and the signal electrode is electrically coupled to the second conductive region of the transistor and isolated from the first conductive region of the transistor. The counter electrode includes a plurality of sub-electrodes electrically connected with each other.

According to one aspect of the invention, a dielectric layer is inserted between every two adjacent sub-electrodes.

According to one aspect of the invention, each sub-electrode includes a TiN layer and a boron doped polysilicon layer.

According to one aspect of the invention, the signal electrode includes Si.

According to one aspect of the invention, the signal electrode has an H-shape structure covering a top surface and two sidewalls of the gate structure.

According to one aspect of the invention, the signal electrode includes two upward extending pillars and a plurality of lateral beams connected the two upward extending pillars.

According to one aspect of the invention, the memory cell structure further includes an active region in the silicon substrate and surrounded by a shallow trench isolation (STI) region, wherein the transistor is formed based on the active region, and the signal electrode includes two upward extending pillars, at least one upward extending pillar laterally expands beyond the active region.

According to one aspect of the invention, a bottom surface of each upward extending pillar covers the active region and the STI region.

According to one aspect of the invention, the signal electrode includes two upward extending pillars with rough surface.

According to one aspect of the invention, the signal electrode comprises n+ Poly Si or Hemispherical-grained Si.

Another embodiment of the present invention provides a memory cell structure. The memory cell structure includes a semiconductor substrate, an active region, a transistor, and a capacitor. The semiconductor substrate has an original semiconductor surface. The active region is in the semiconductor substrate and surrounded by a shallow trench isolation (STI) region. The transistor is formed based on the active region, and the transistor includes a gate structure, a first conductive region, and a second conductive region. The capacitor has a signal electrode and a counter electrode, the capacitor is over the transistor, and the signal electrode is electrically coupled to the second conductive region of the transistor and isolated from the first conductive region of the transistor. The signal electrode includes two upward extending pillars, and each upward extending pillar stacks over the active region and laterally expands beyond the active region.

According to one aspect of the invention, the gate structure includes a gate conductive region and a cap dielectric region above the gate conductive region, and a top surface of the gate conductive region is lower than the original semiconductor surface.

According to one aspect of the invention, the counter electrode includes a plurality of sub-electrodes electrically connected with each other, each sub-electrode comprises a TiN layer and a boron doped polysilicon layer, and the signal electrode includes Si.

According to one aspect of the invention, the signal electrode has an H-shape structure covering a top surface and two sidewalls of the gate structure.

According to one aspect of the invention, the memory cell structure further includes a bit line and a connecting plug. The bit line is disposed under the original semiconductor surface. The connecting plug electrically connects the bit line to the first conductive region of the transistor.

According to one aspect of the invention, the bit line is disposed within the STI region, and the STI region comprises a set of asymmetric material spacers.

Another embodiment of the present invention provides a memory cell structure. The memory cell structure includes a semiconductor substrate, an active region, a transistor, and a capacitor. The semiconductor substrate has an original semiconductor surface. The active region is in the semiconductor substrate and surrounded by a shallow trench isolation (STI) region. The transistor is formed based on the active region, and the transistor includes a gate structure, a first conductive region, and a second conductive region. The capacitor has a signal electrode and a counter electrode, the signal electrode covers a top surface and two sidewalls of the gate structure, and the signal electrode is electrically coupled to the second conductive region of the transistor and isolated from the first conductive region of the transistor. The signal electrode includes two upward extending pillars with rough surface, and each upward extending pillar includes n+ Poly Si or Hemispherical-grained Si.

According to one aspect of the invention, the counter electrode comprises a plurality of sub-electrodes electrically connected with each other, and a dielectric layer is inserted between every two adjacent sub-electrodes.

According to one aspect of the invention, each sub-electrode comprises a TiN layer and a boron doped polysilicon layer.

According to one aspect of the invention, the memory cell structure further includes a bit line and a connecting plug. The bit line is disposed under the original semiconductor surface. The connecting plug electrically connects the bit line to the first conductive region of the transistor. The bit line is disposed within the STI region, and the STI region includes a set of asymmetric material spacers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a flowchart illustrating a manufacturing method of the 1T1C memory cells according to an embodiment of the present invention.

FIG. 1B, FIG. 1C, FIG. 1D, FIG. 1E, FIG. 1F, FIG. 1G, FIG. 1H are diagrams illustrating FIG. 1A.

FIG. 2 shows defining active regions of access transistors of the 1T1C memory cells.

FIG. 3, FIG. 4, FIG. 5 show forming underground bit lines connecting to the access transistors.

FIG. 6, FIG. 7, FIG. 8 show forming word lines connecting to the access transistors and gates of the access transistors.

FIG. 9, FIG. 10, FIG. 11 show defining memory cells isolation with drain regions and source regions of the access transistors of the 1T1C memory cells.

FIG. 12, FIG. 13, FIG. 14, FIG. 15 show forming connections between underground bit lines and the drain regions of the access transistors.

FIG. 16, FIG. 17, FIG. 18, FIG. 19, FIG. 20, FIG. 21, FIG. 22, FIG. 23, FIG. 24, FIG. 25, FIG. 26, FIG. 27, FIG. 28 show forming the H-shape capacitors over the access transistors with connections to the source regions of the access transistors.

FIG. 18A, FIG. 19A show through n+ SEG lateral growth to maximize the electrode area of the H-capacitor to get larger capacitance of the H-capacitor for bigger signal storage according to another embodiment of the present invention.

FIG. 26A, FIG. 27A, FIG. 28A show by combining n+ Poly or HSG selective growth to further enhance the H-capacitor bottom electrode area to get larger capacitance of the H-capacitor for signal storage according to another embodiment of the present invention.

FIG. 28B, FIG. 29, FIG. 30, FIG. 31, FIG. 32, FIG. 33, FIG. 34, FIG. 35 show how to form a ladder type H-capacitor according to another embodiment of the present invention.

### DETAILED DESCRIPTION

Herewith introduces a new HCoT (an H-shape capacitor positioned directly over to clamp an access transistor) cell with a process to implement the 1T1C memory cell structure in the following.

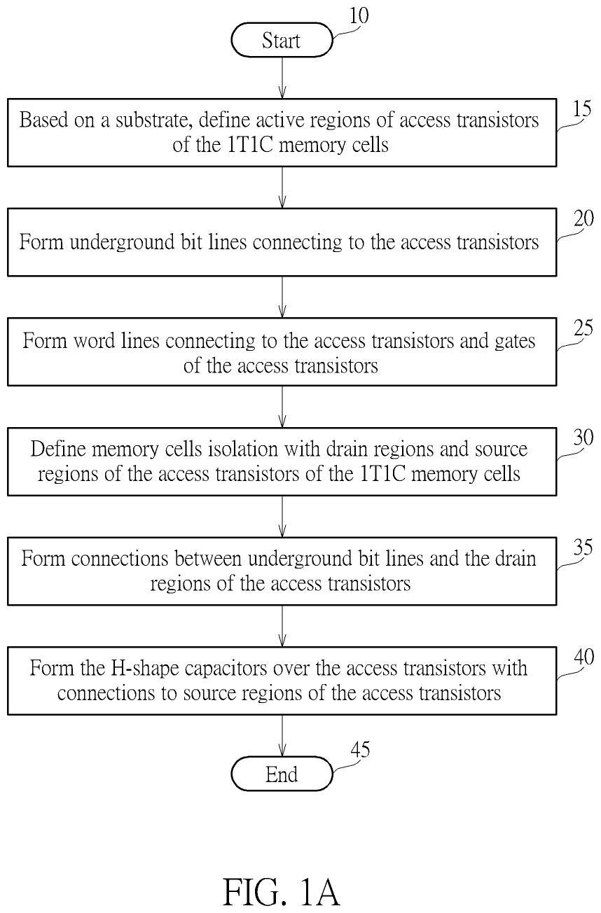

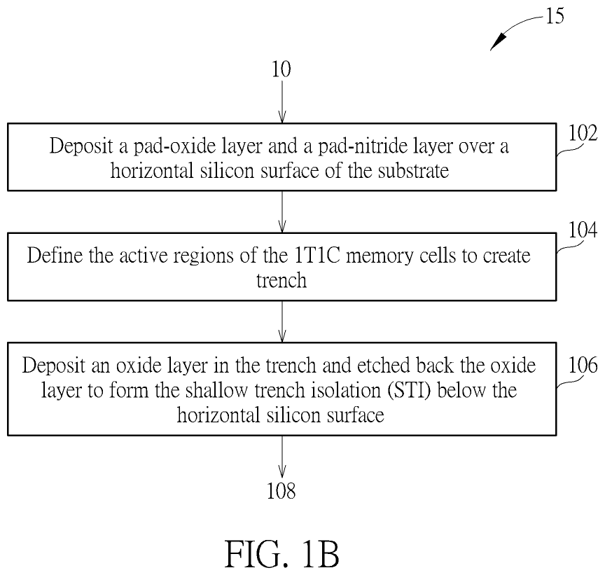

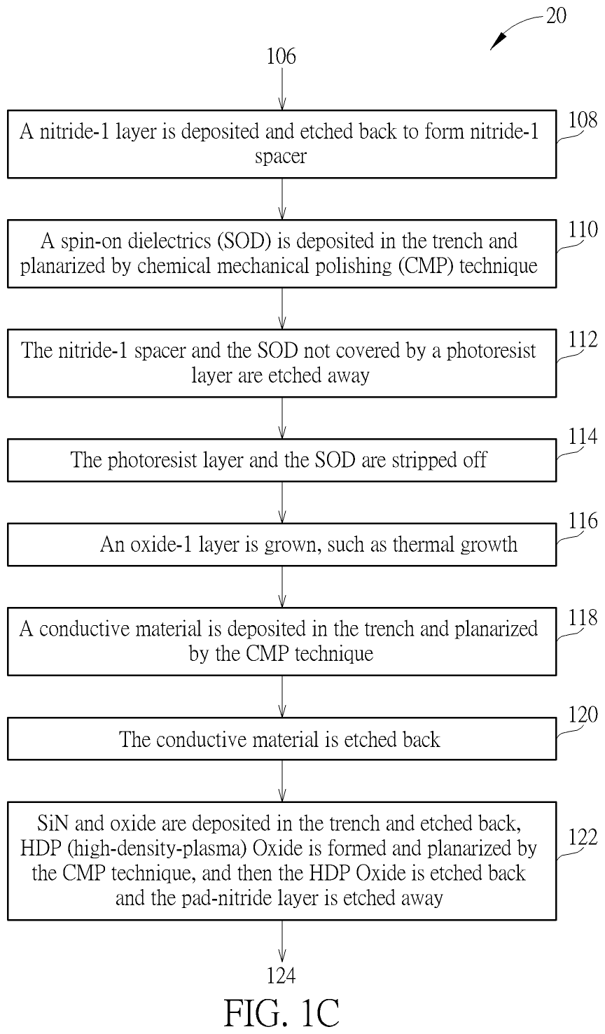

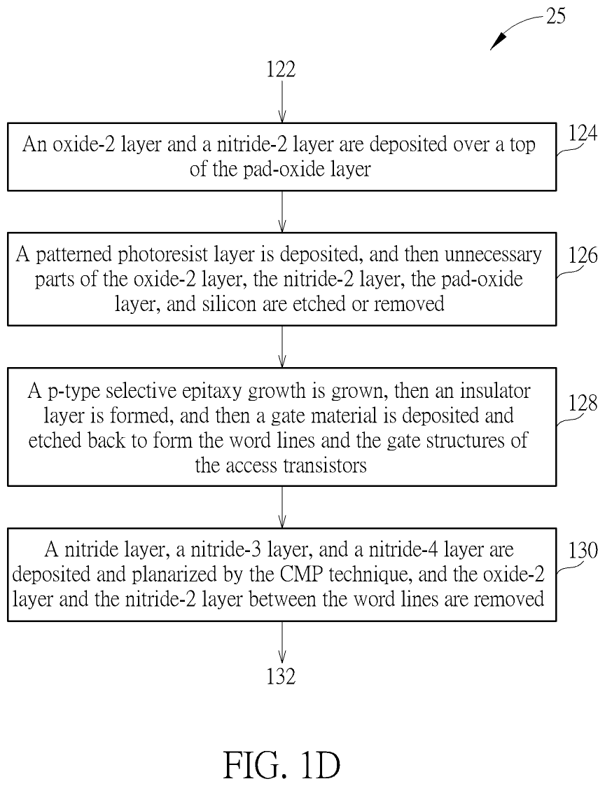

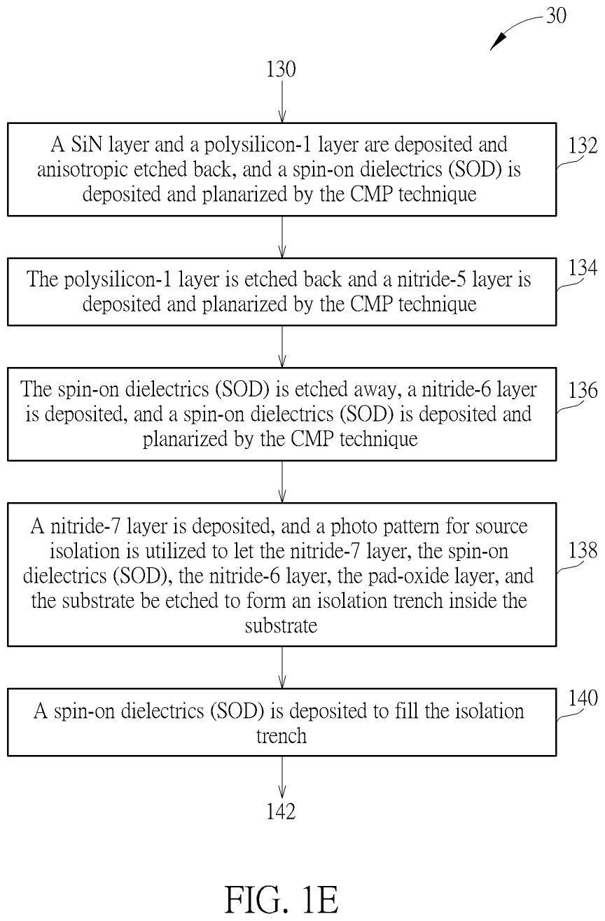

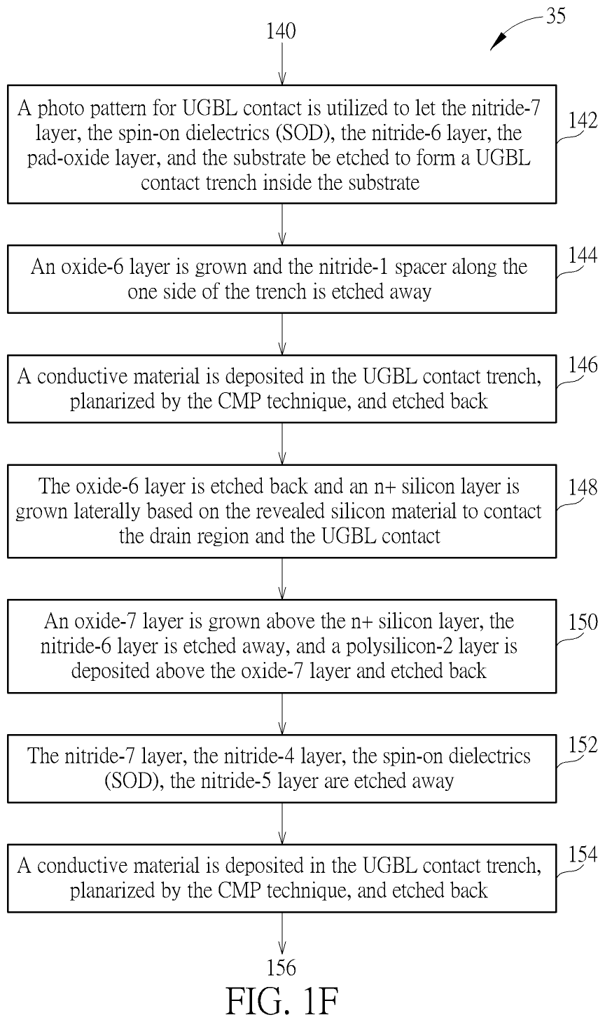

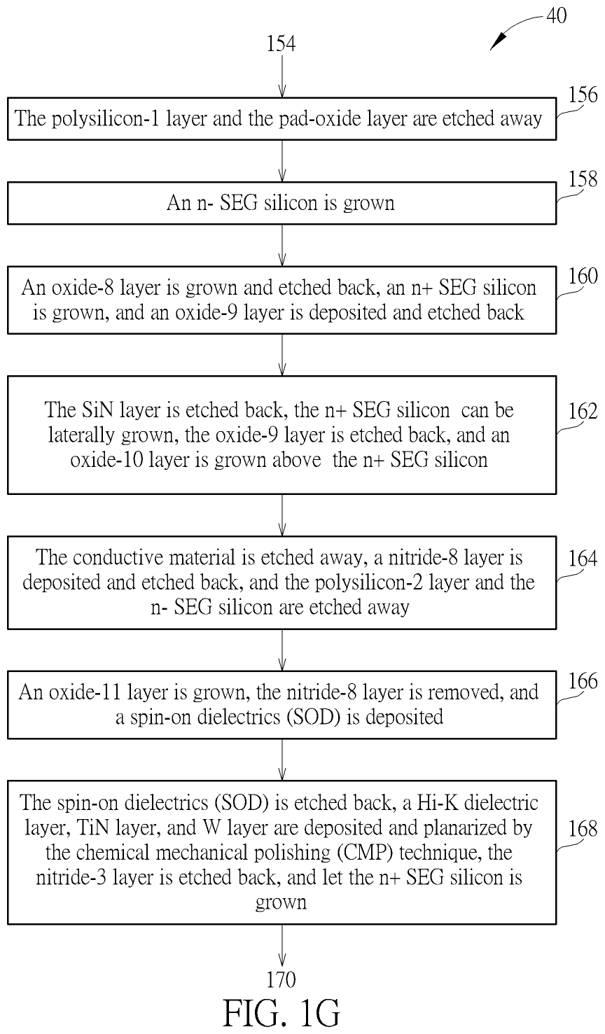

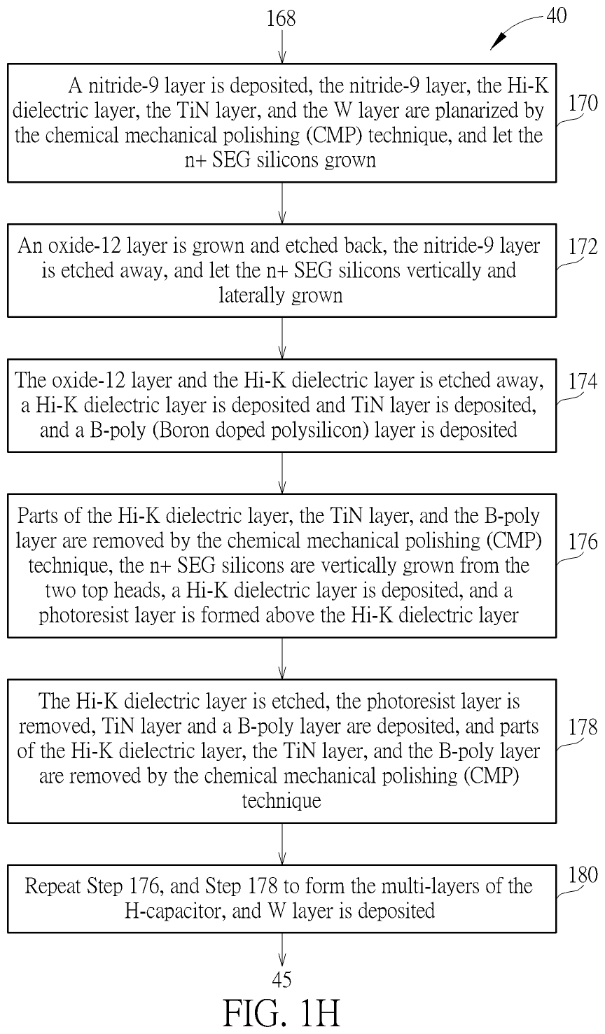

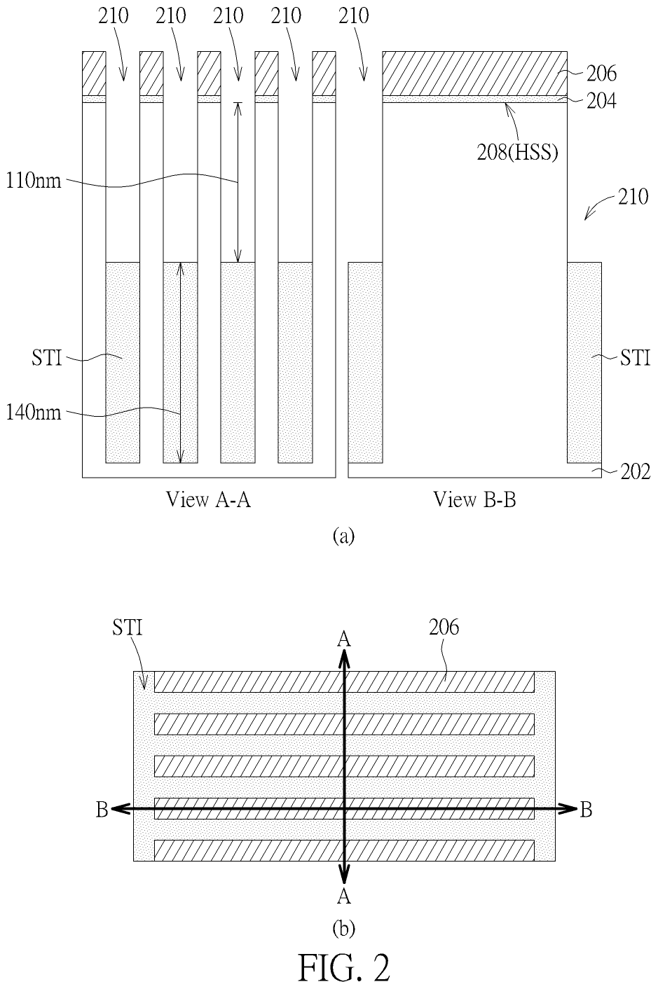

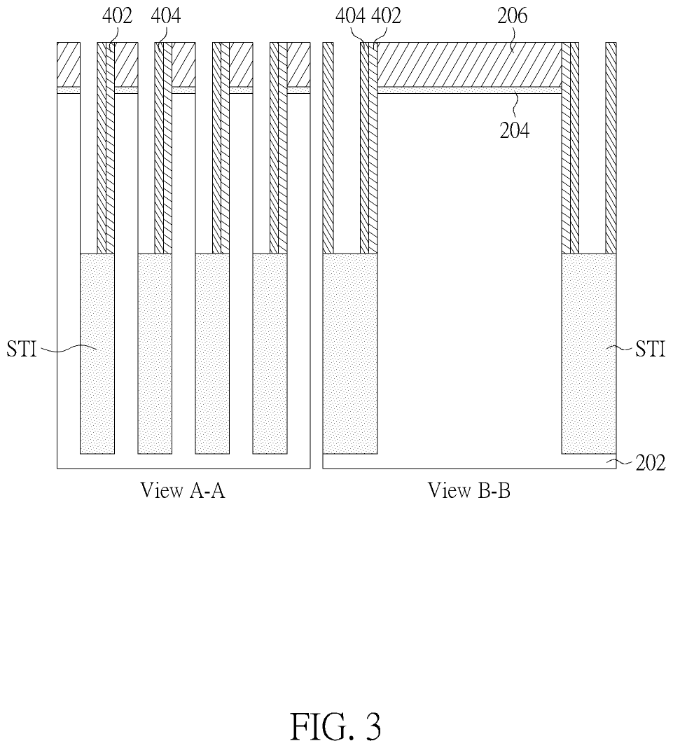

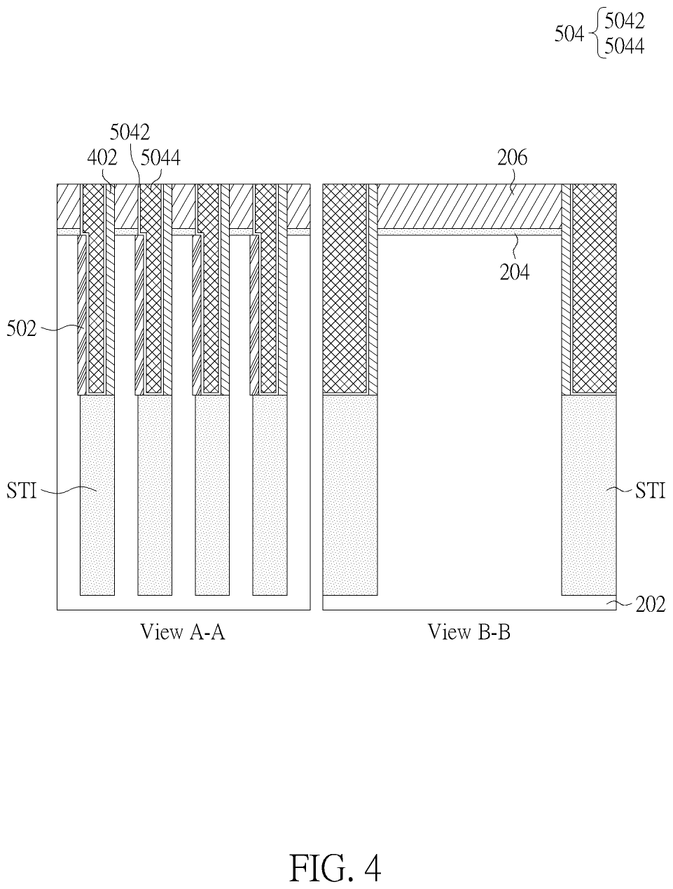

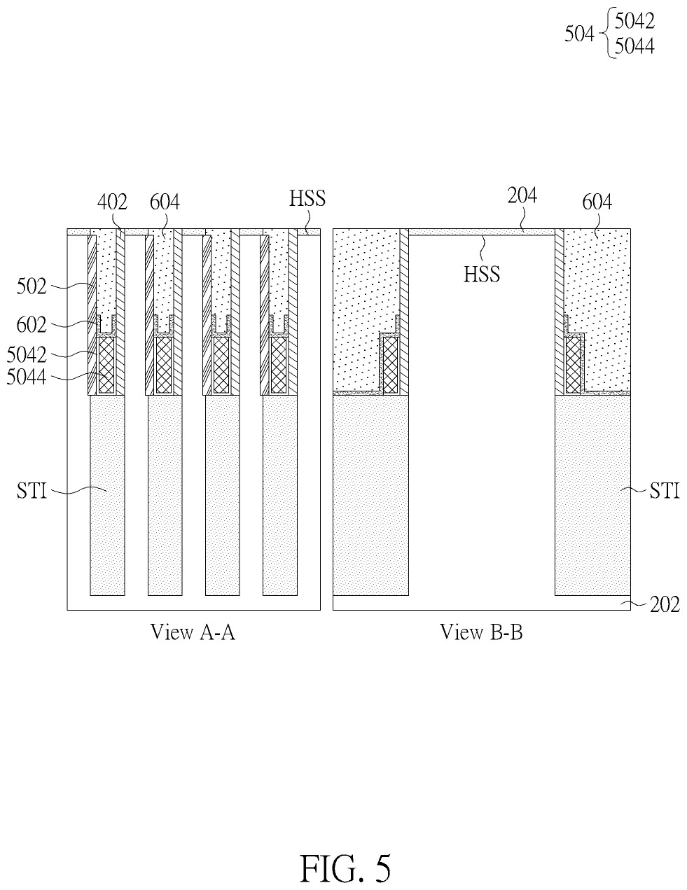

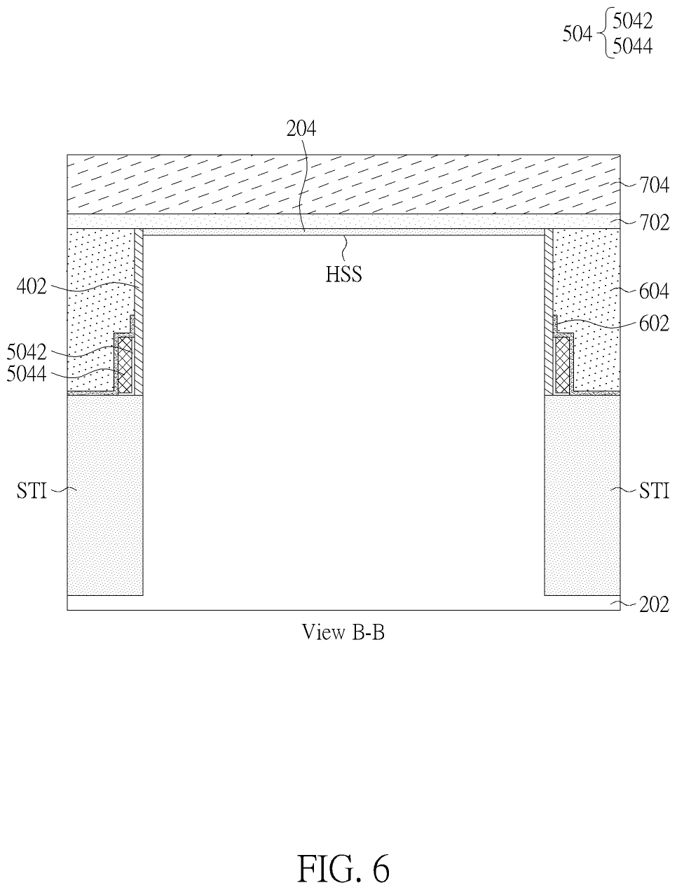

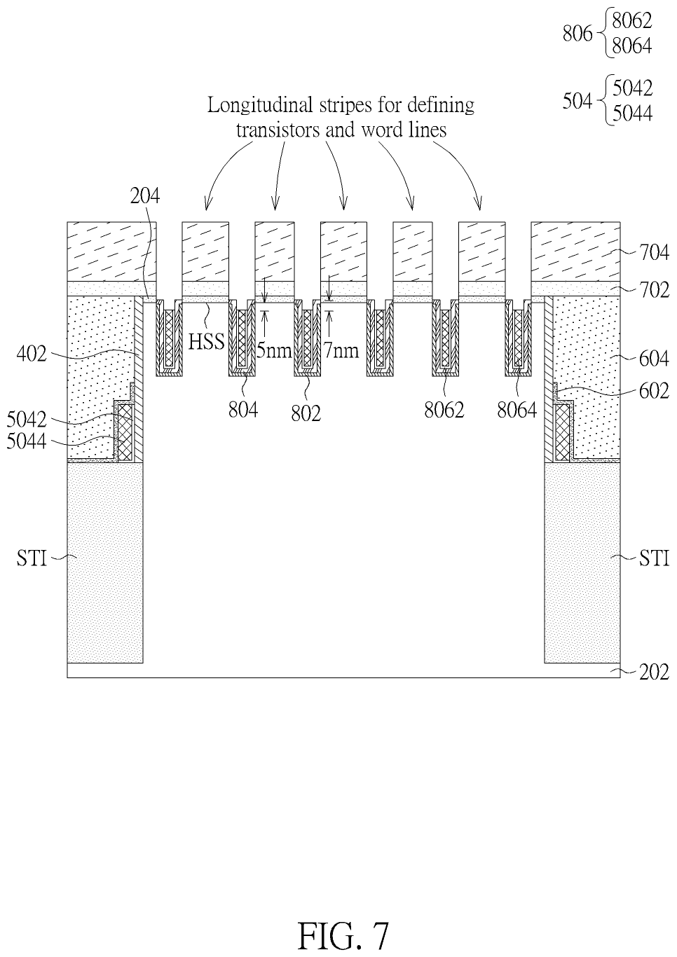

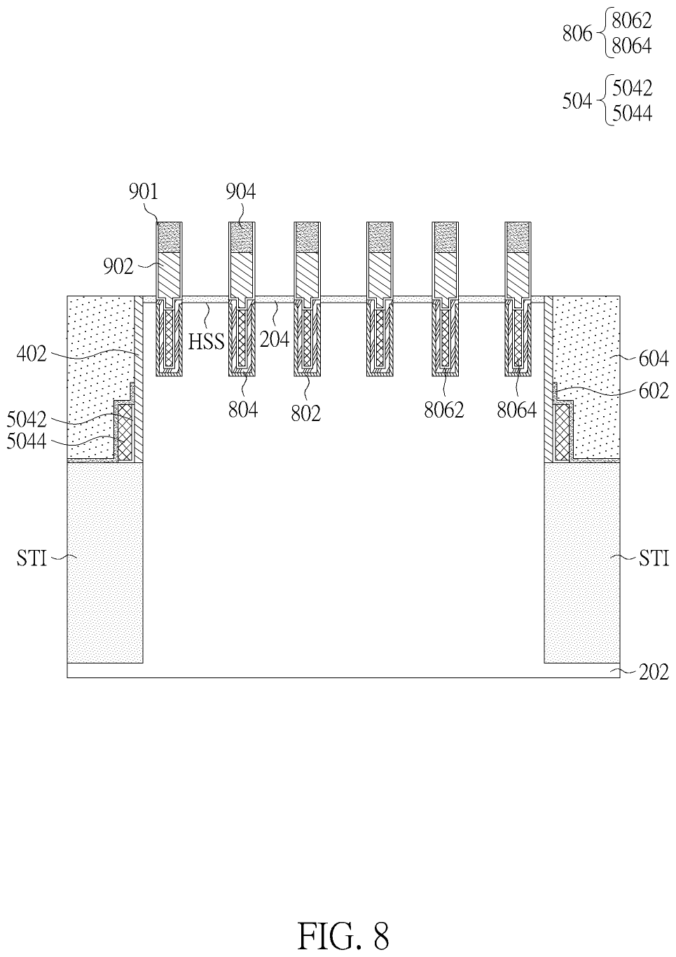

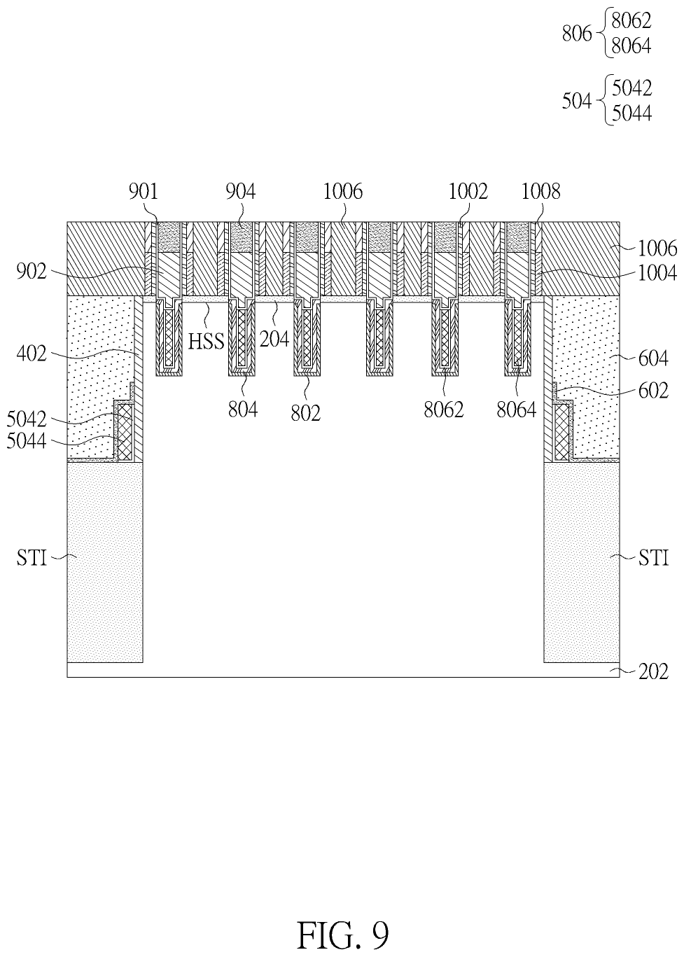

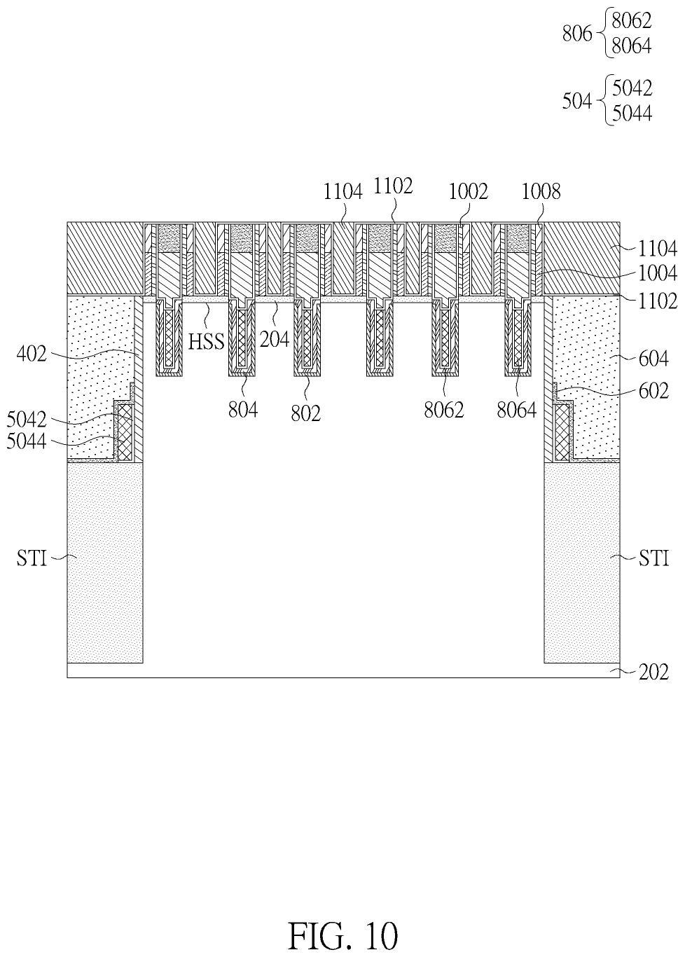

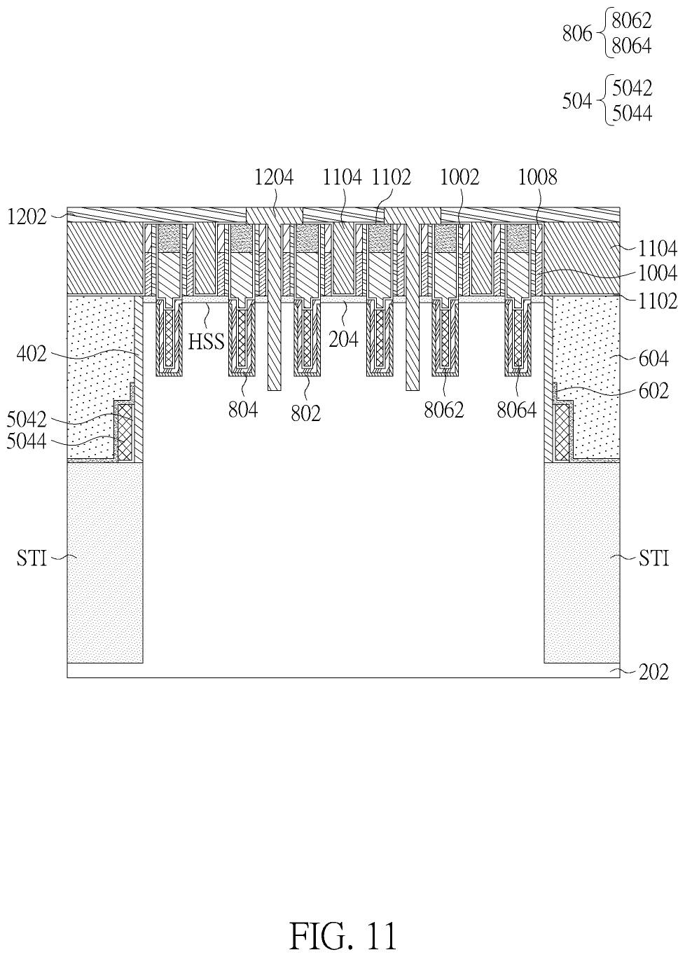

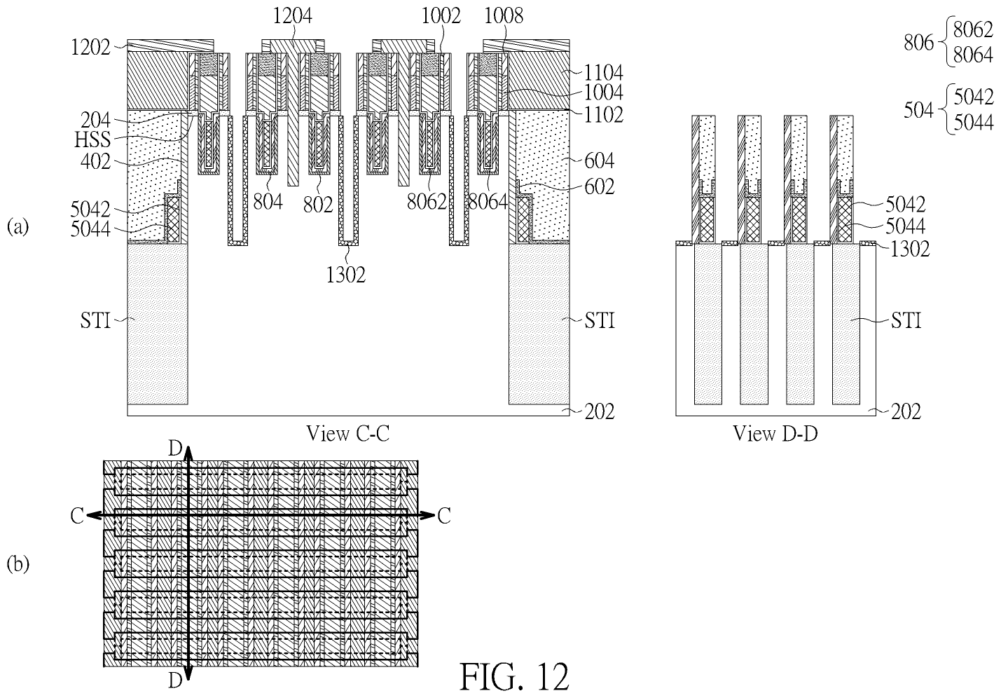

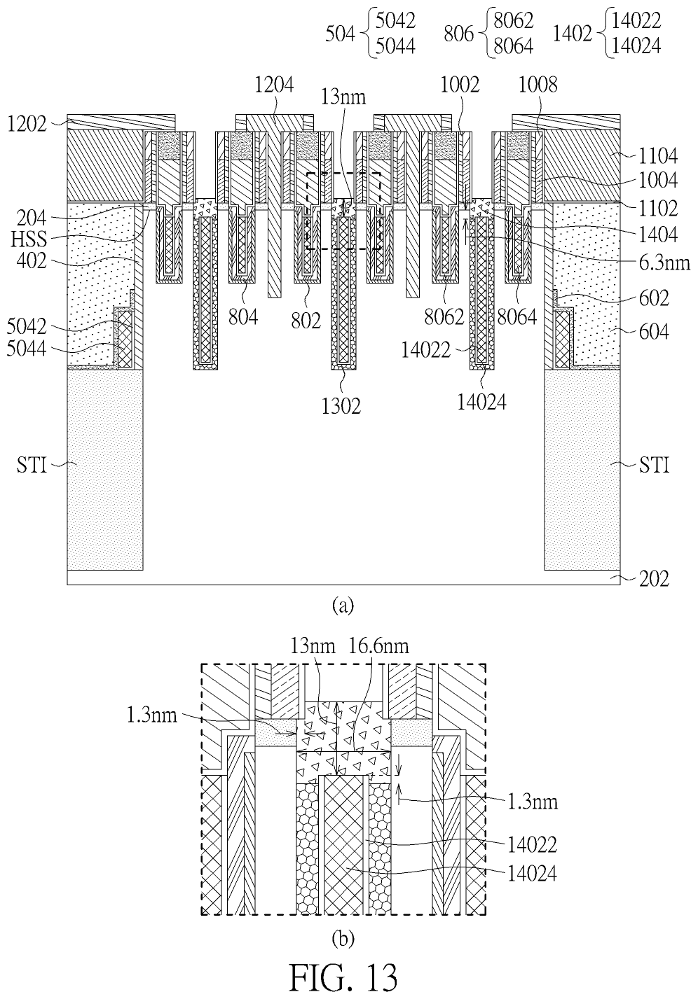

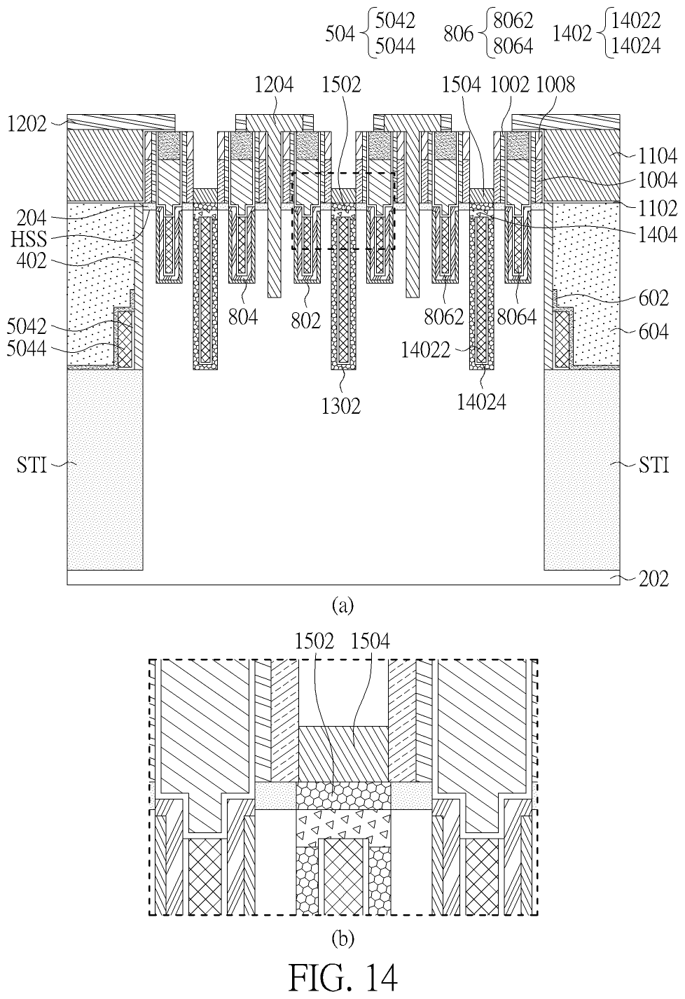

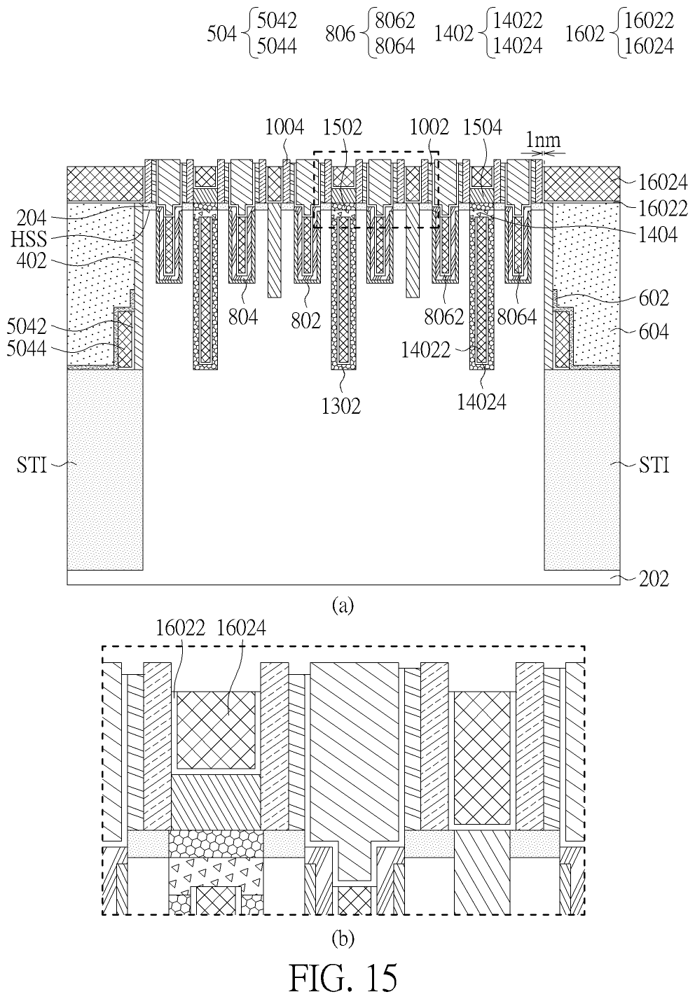

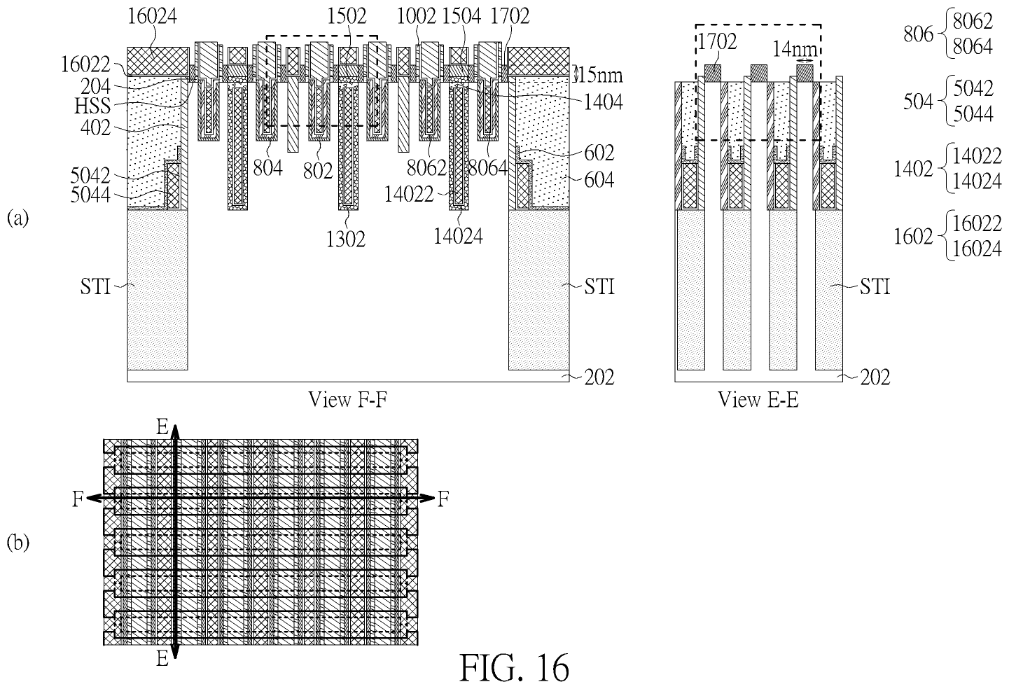

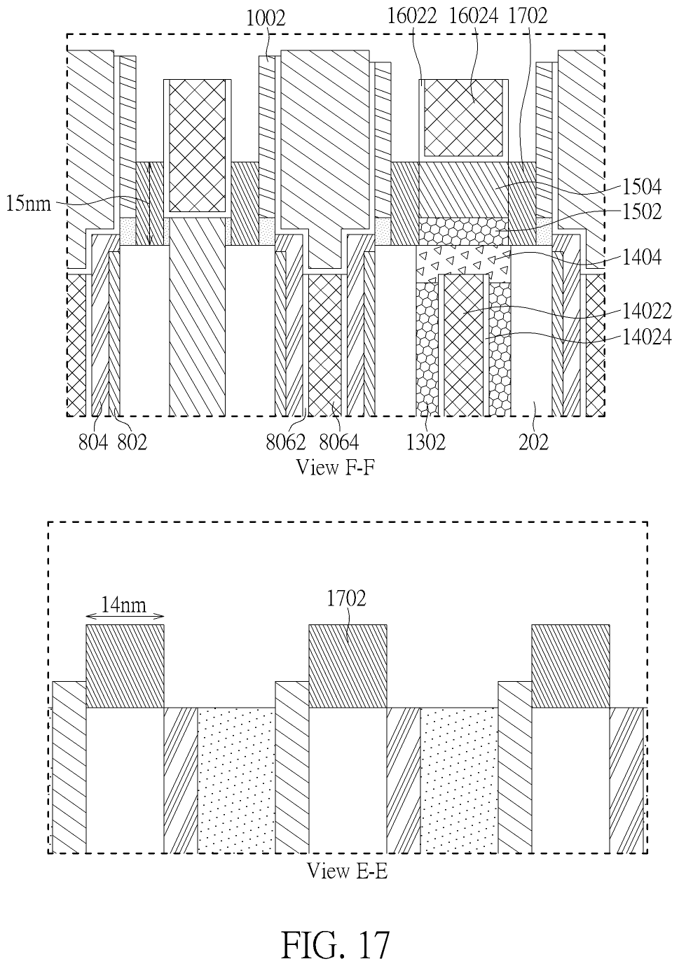

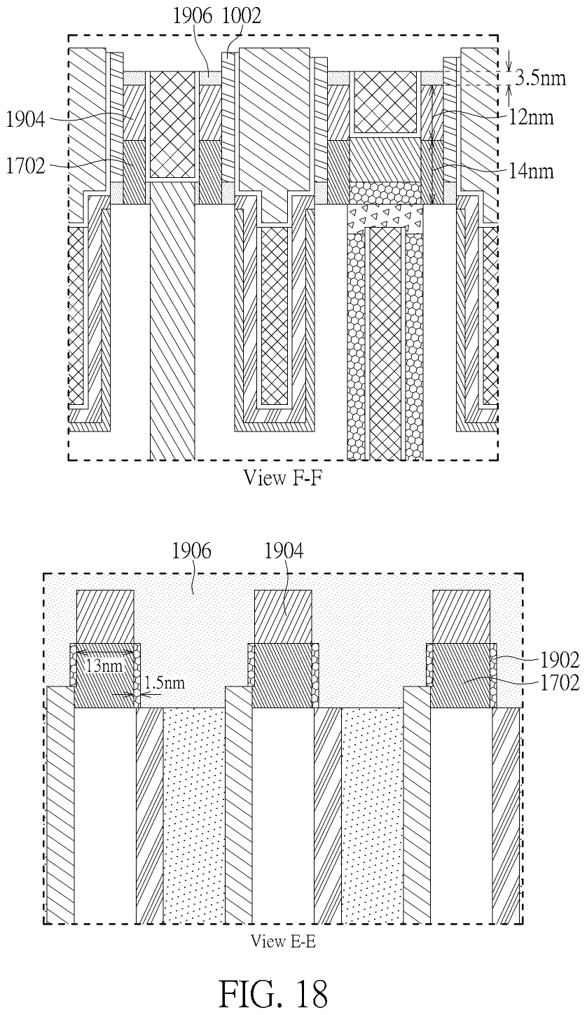

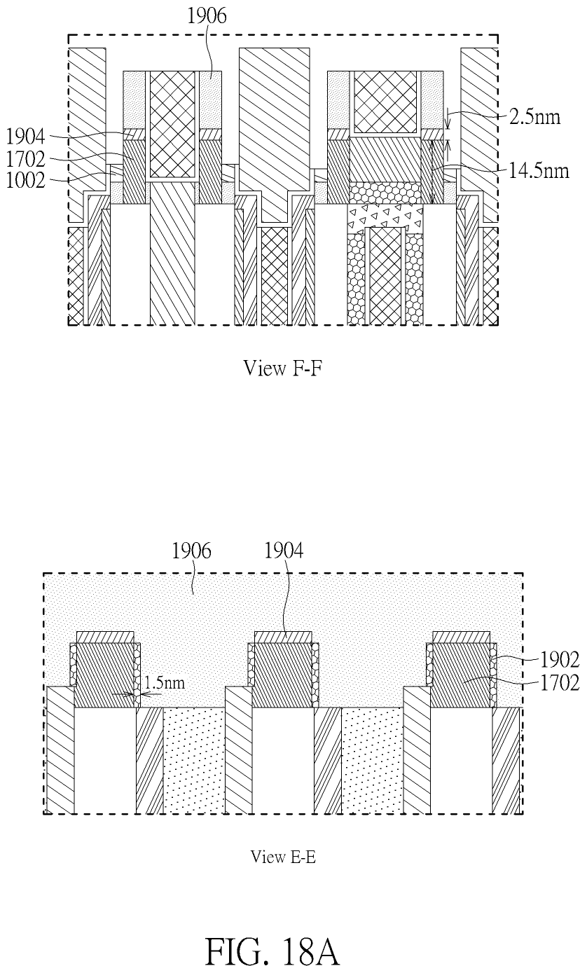

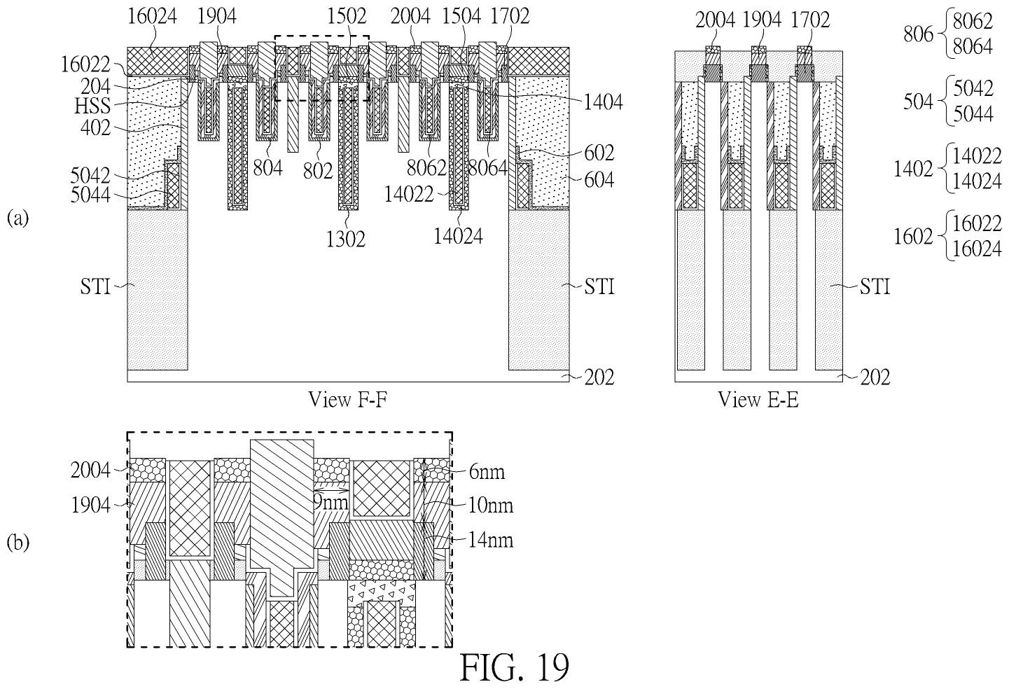

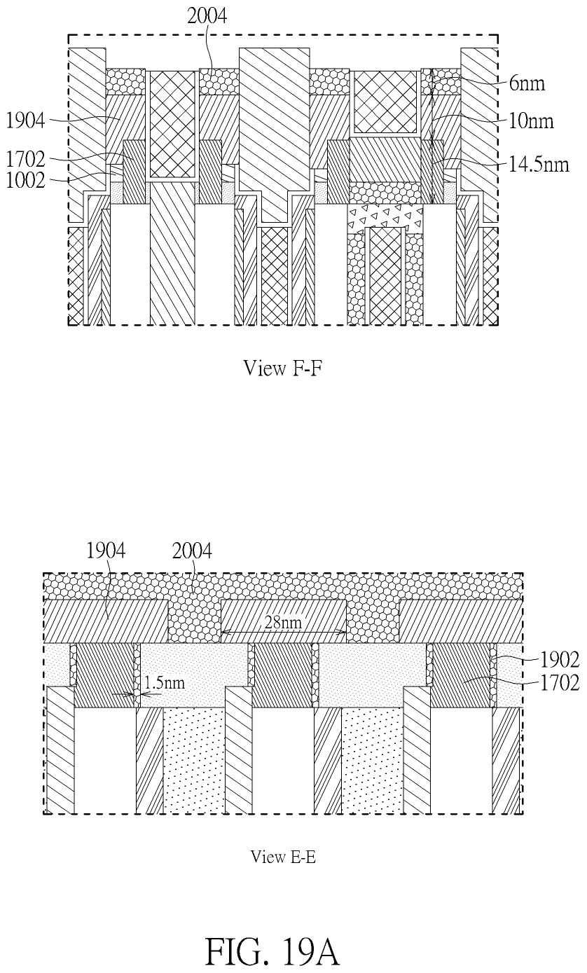

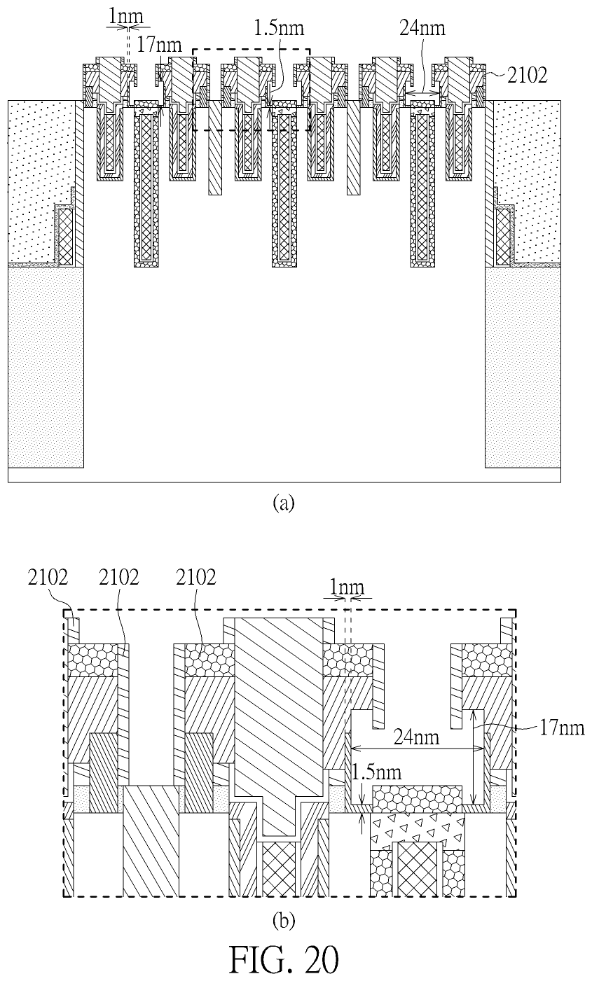

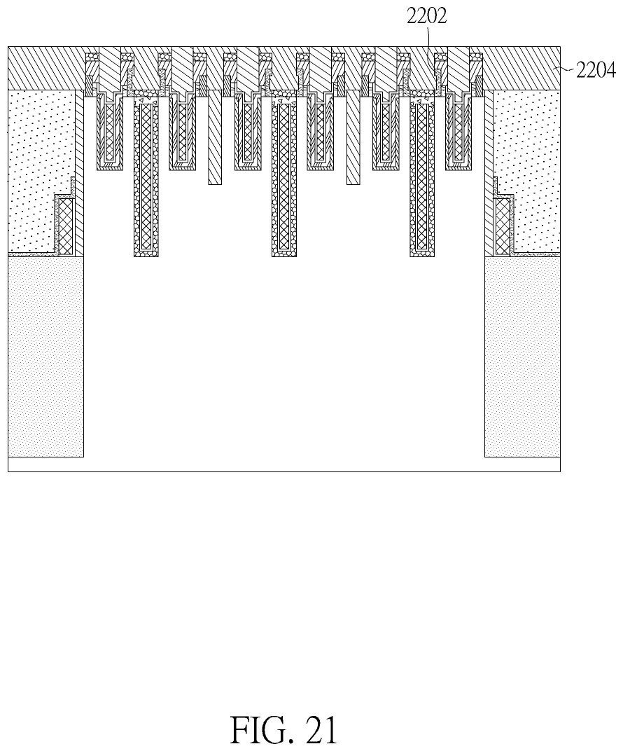

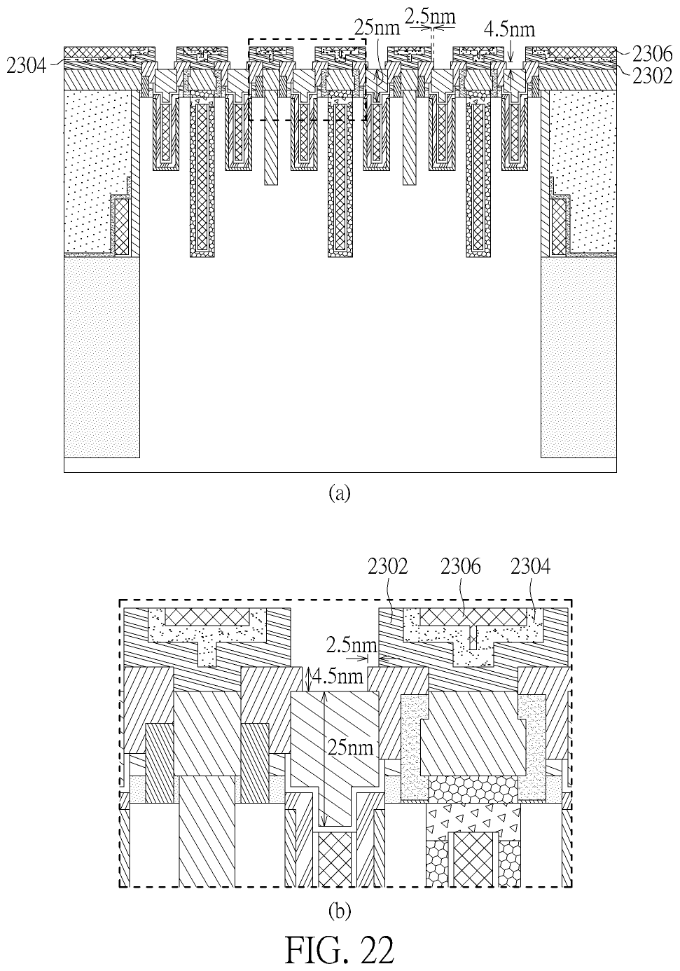

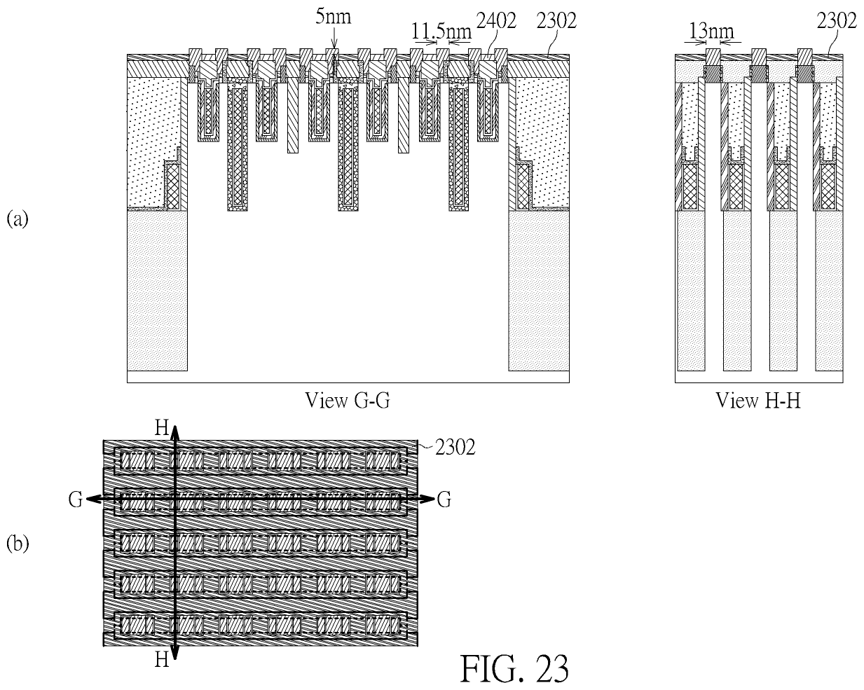

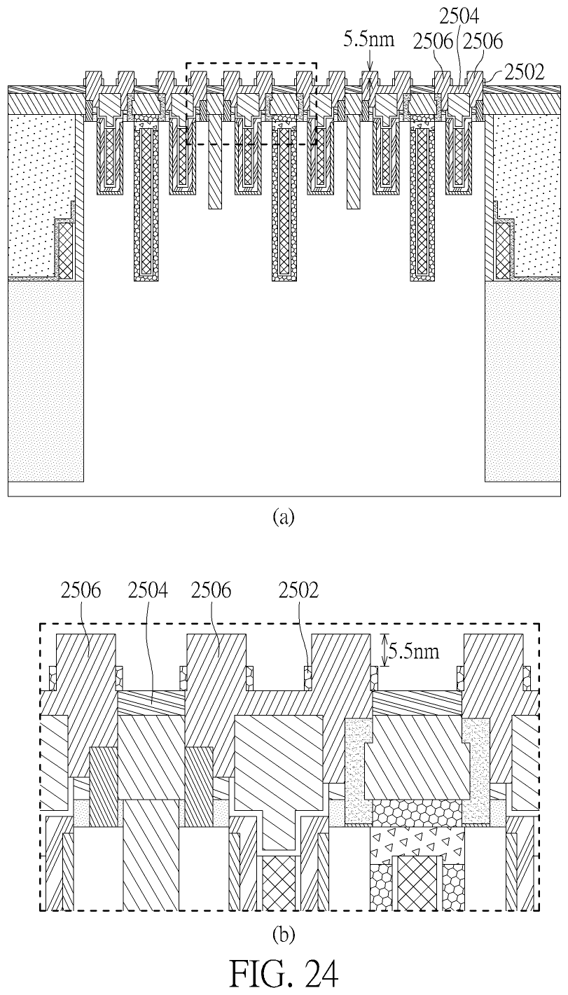

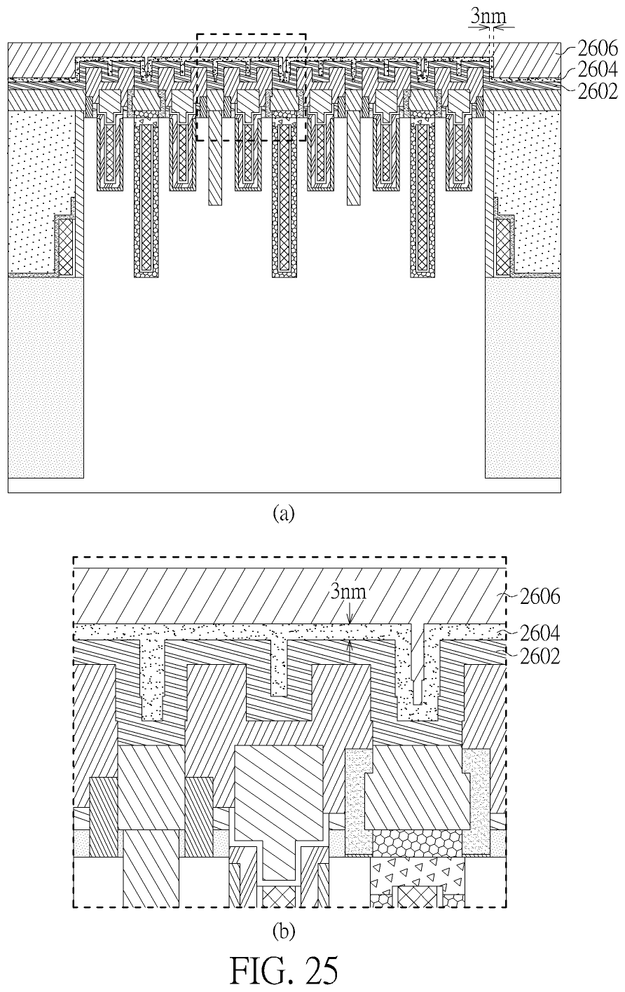

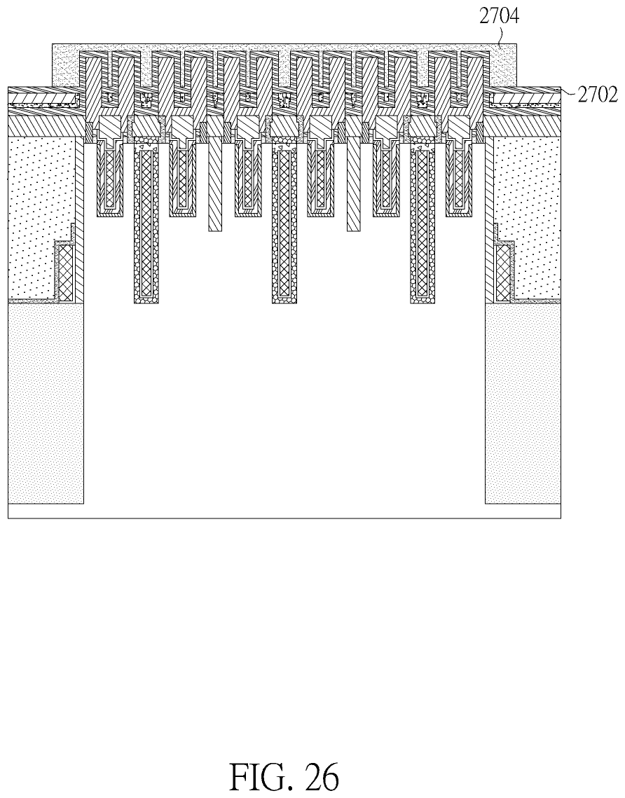

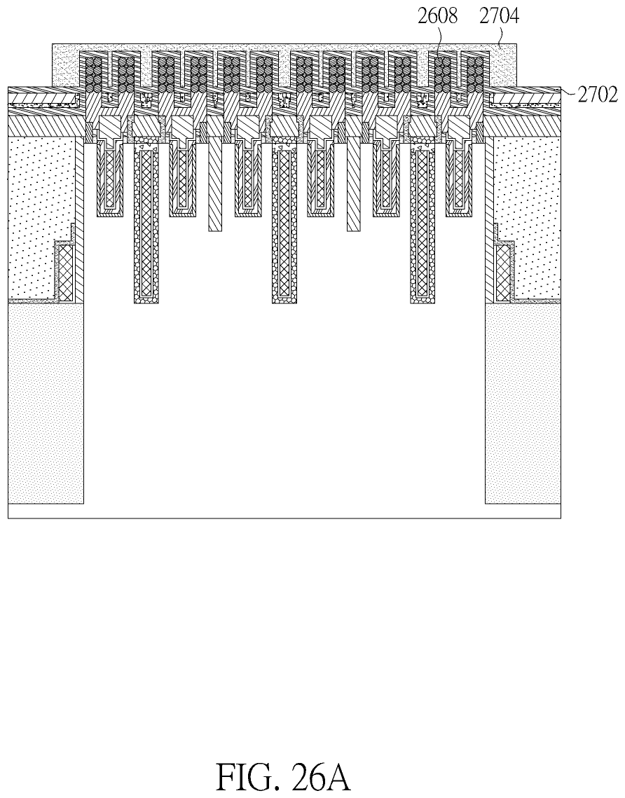

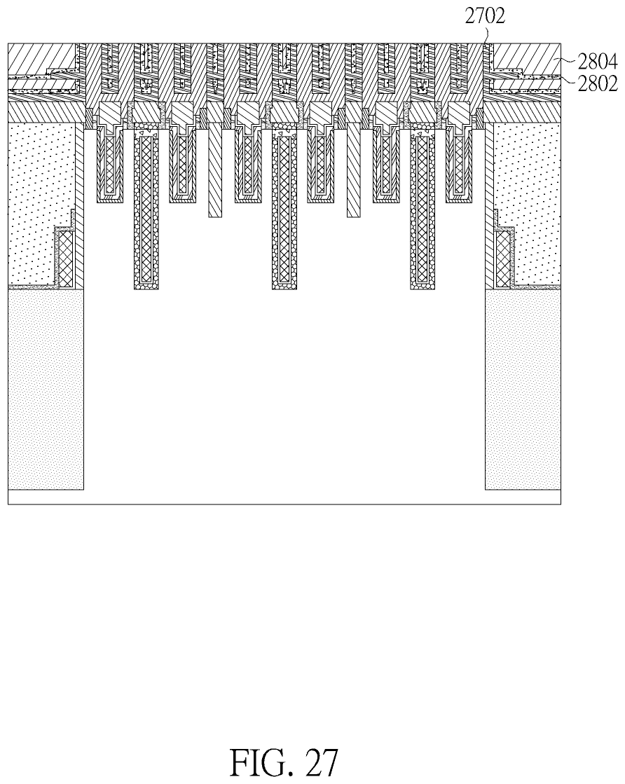

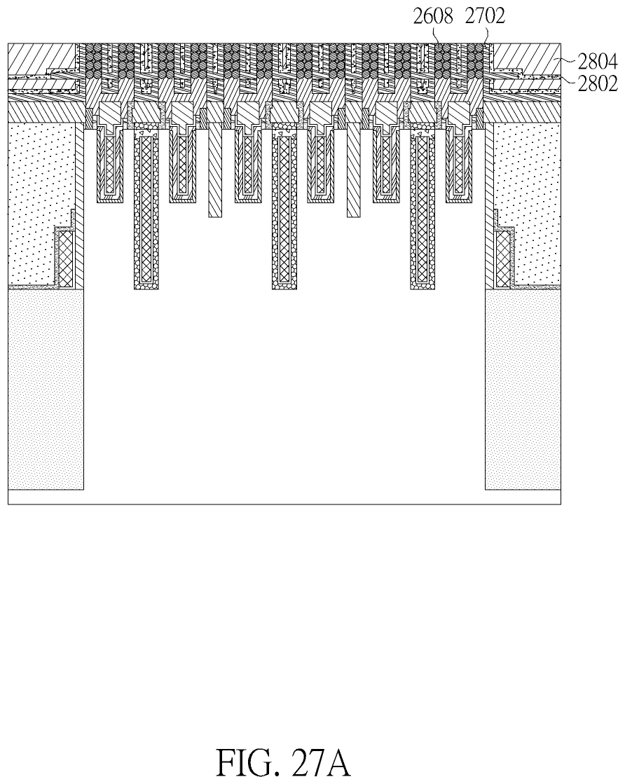

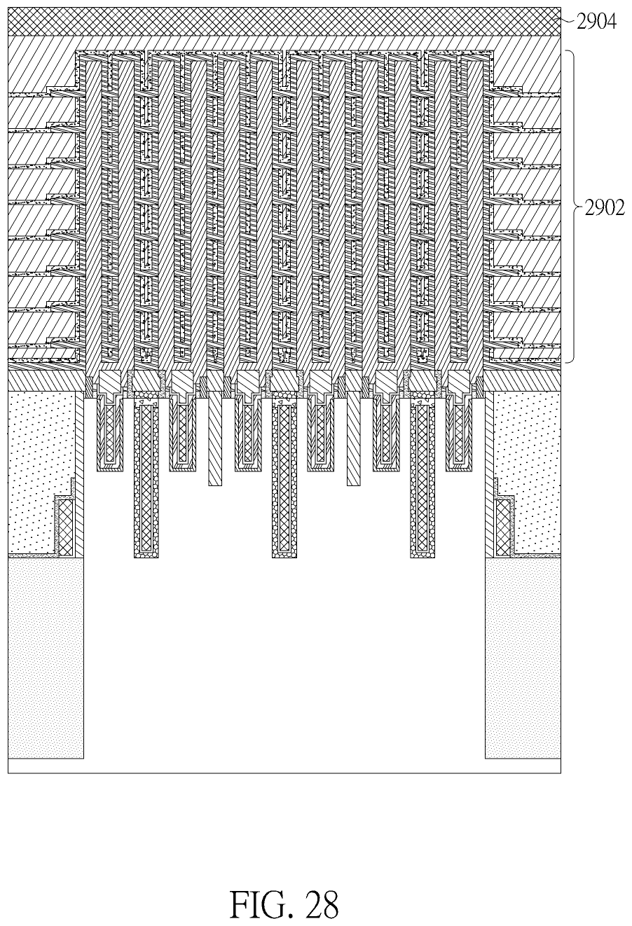

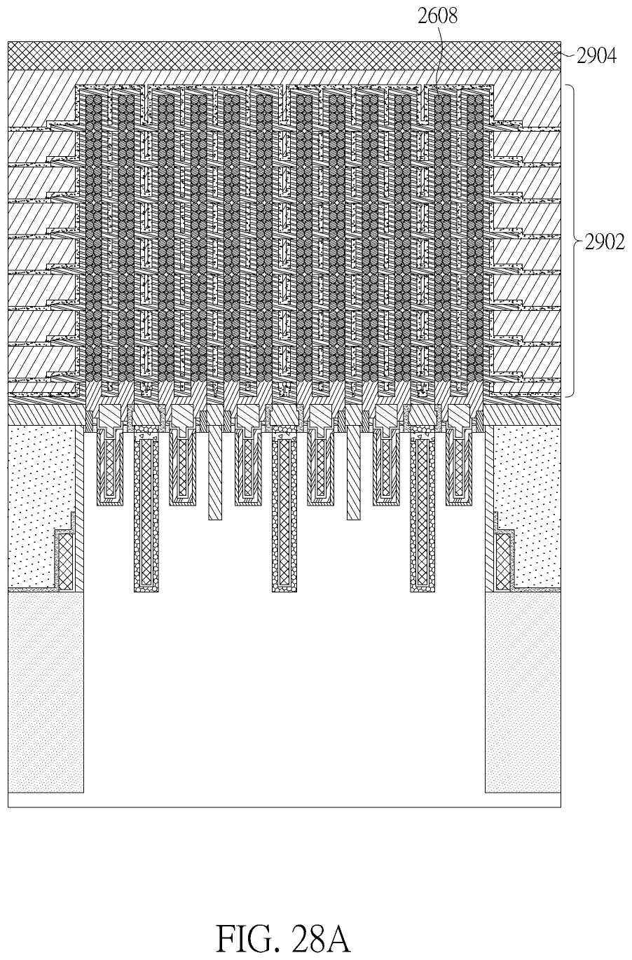

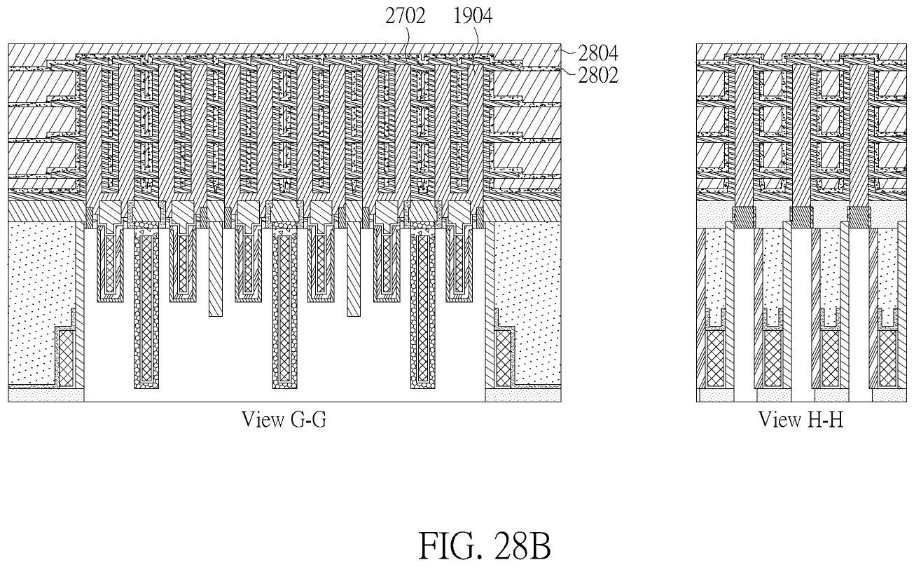

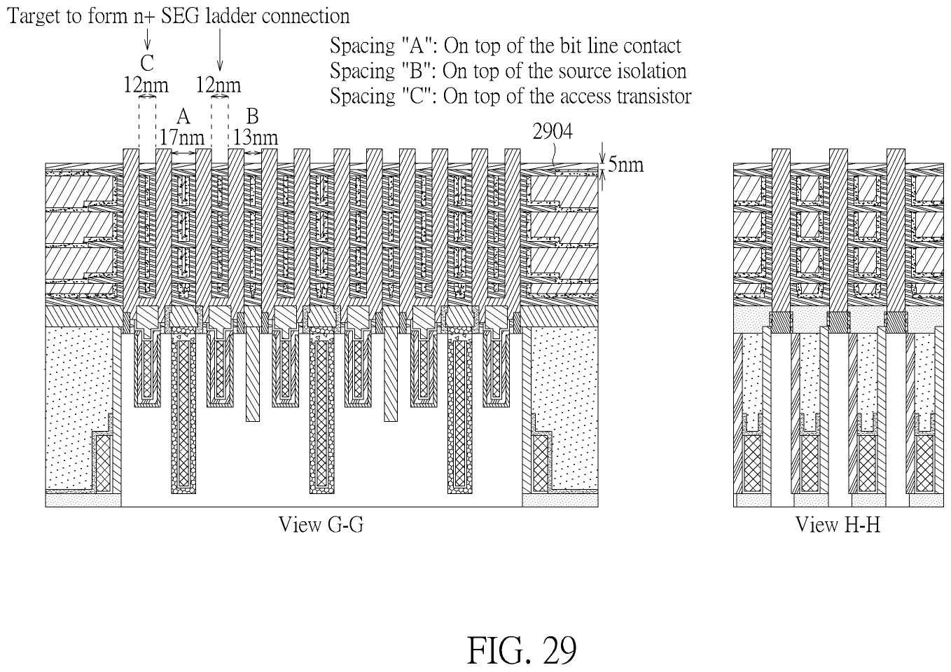

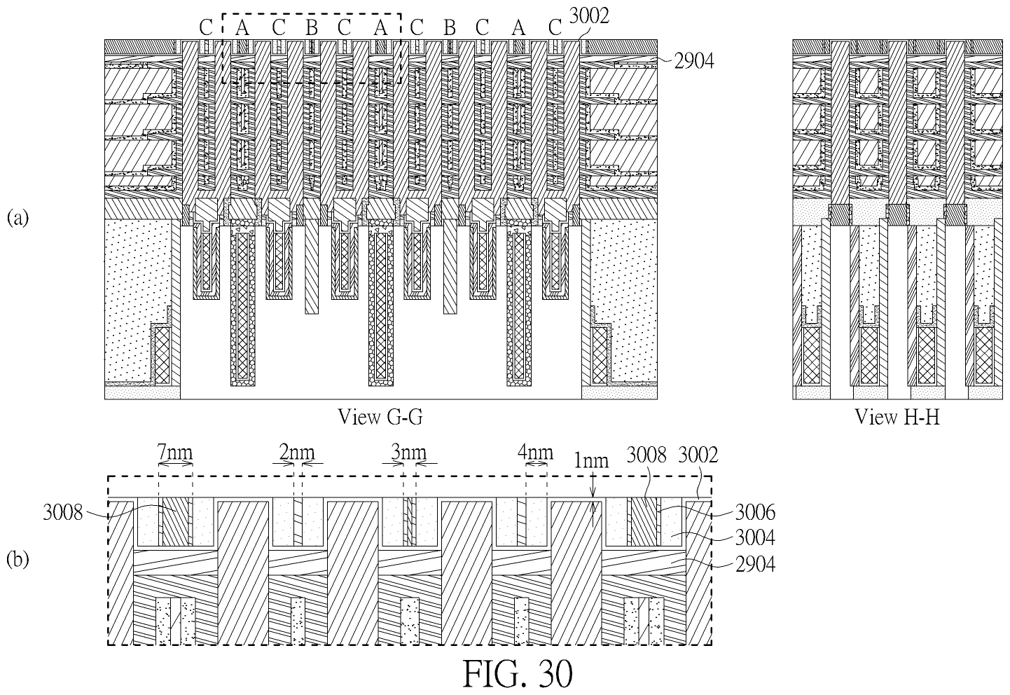

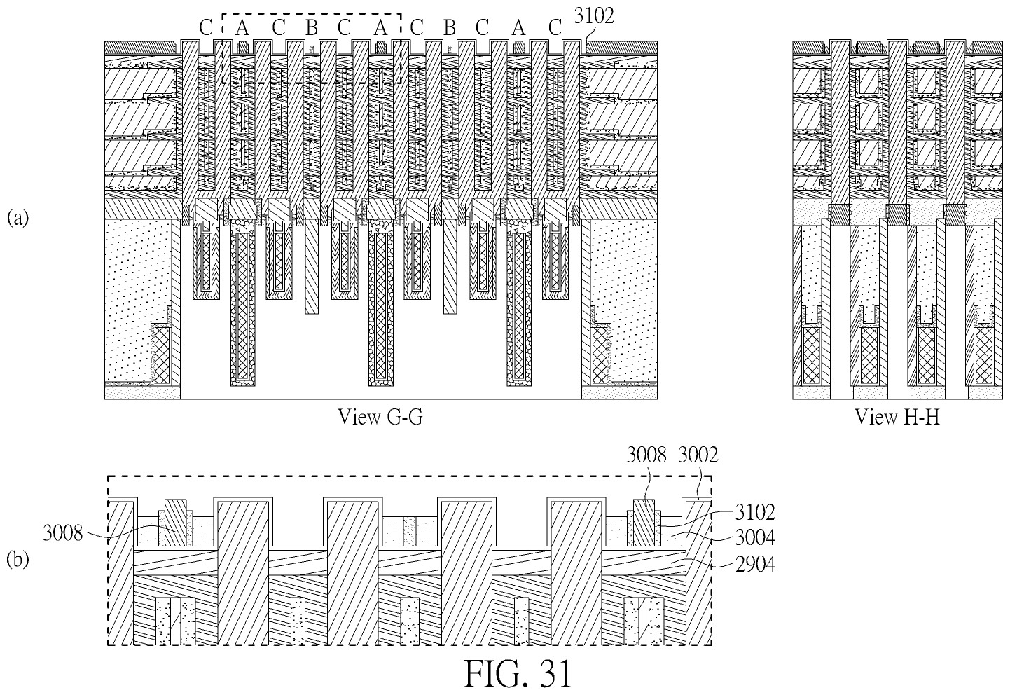

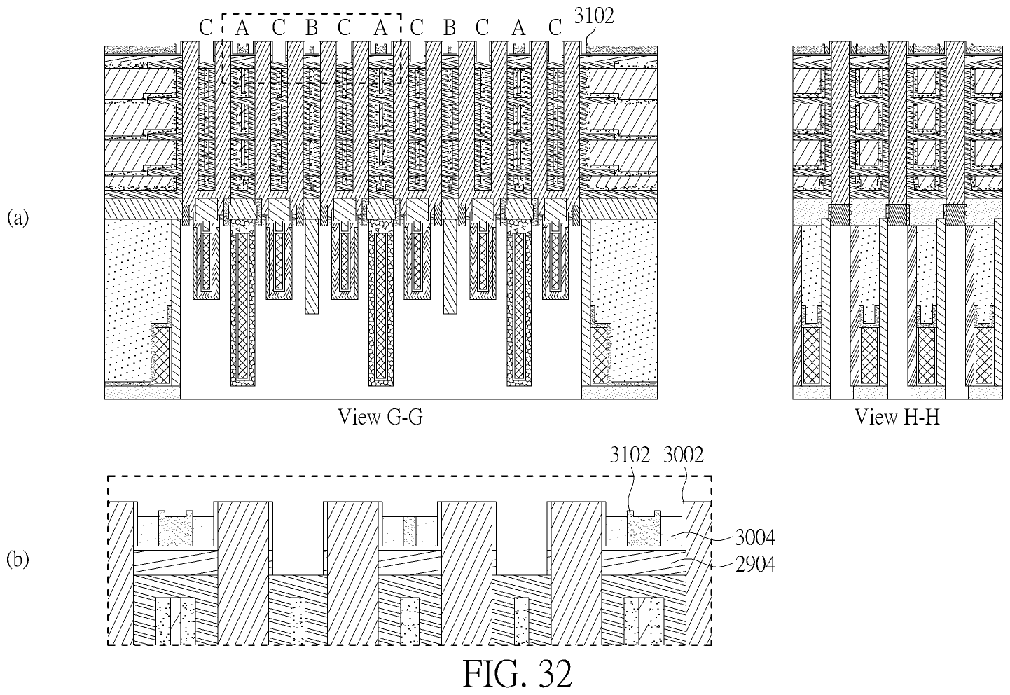

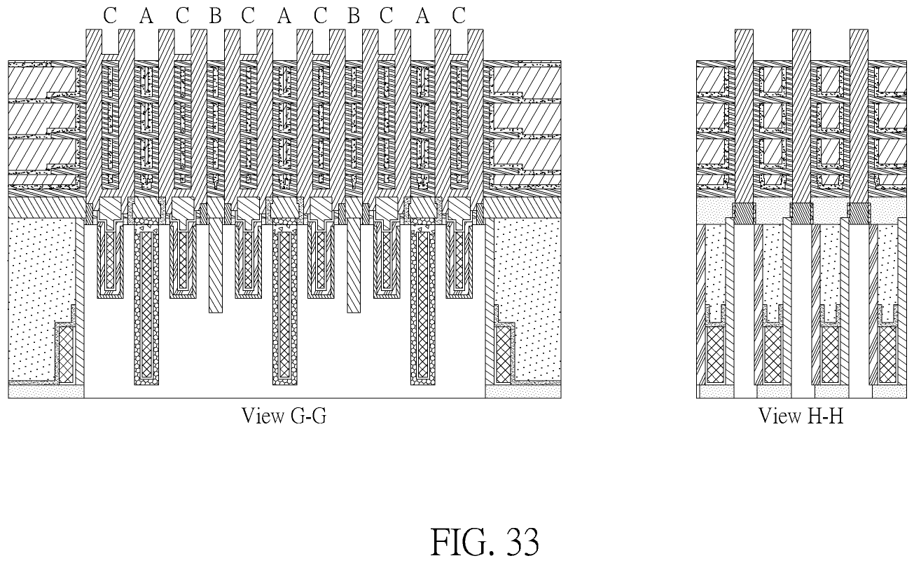

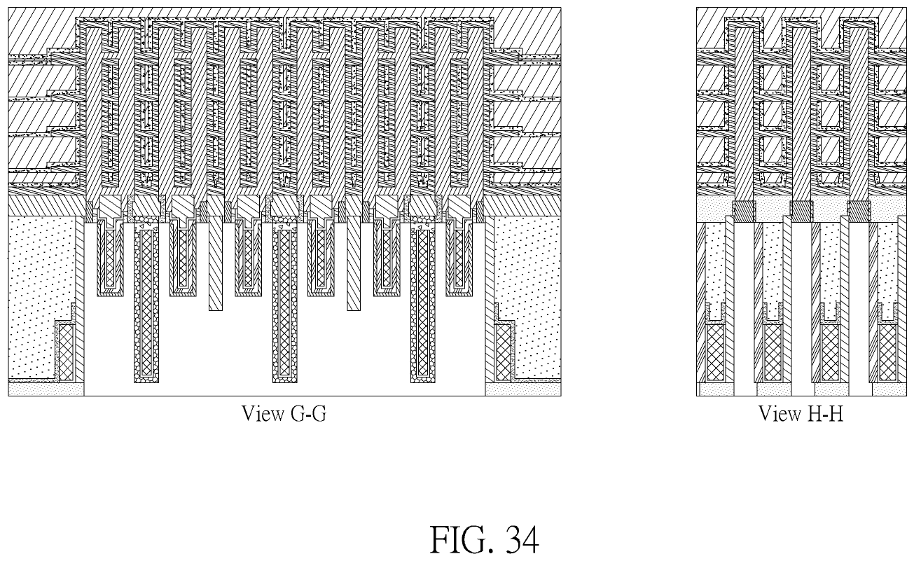

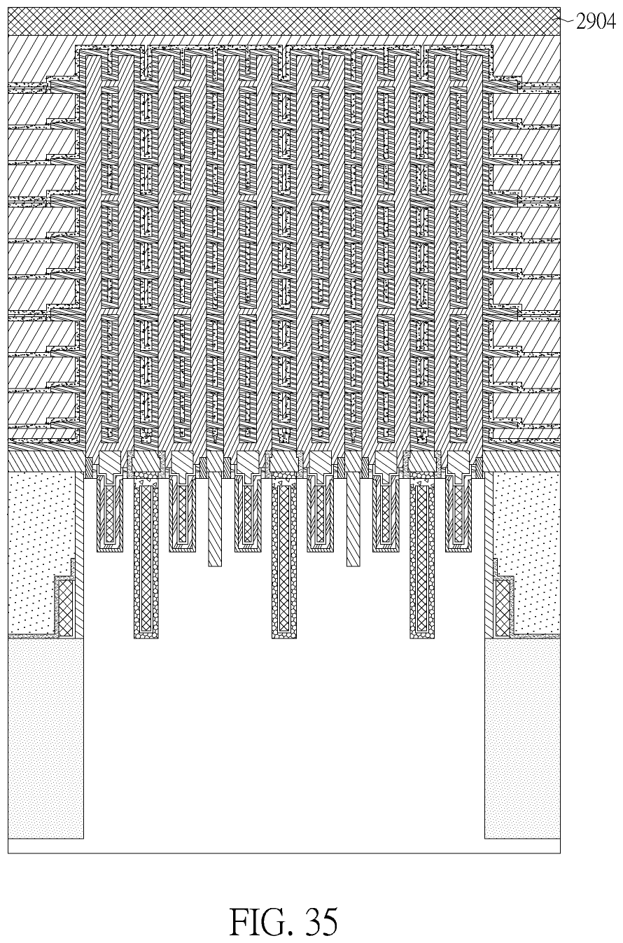

Next, please refer to FIG. 1A, FIG. 1B, FIG. 1C, FIG. 1D, FIG. 1E, FIG. 1F, FIG. 1G, FIG. 1H, FIG. 2, FIG. 3, FIG. 4, FIG. 5, FIG. 6, FIG. 7, FIG. 8, FIG. 9, FIG. 10, FIG. 11, FIG. 12, FIG. 13, FIG. 14, FIG. 15, FIG. 16, FIG. 17, FIG. 18, FIG. 18A, FIG. 19, FIG. 19A, FIG. 20, FIG. 21, FIG. 22, FIG. 23, FIG. 24, FIG. 25, FIG. 26, FIG. 26A, FIG. 27, FIG. 27A, FIG. 28, FIG. 28A, FIG. 28B, FIG. 29, FIG. 30, FIG. 31, FIG. 32, FIG. 33, FIG. 34, FIG. 35, wherein FIG. 1A is a flowchart illustrating a manufacturing method of the 1T1C memory cells according to an embodiment of the present invention.

Step 10: Start.

Step 15: Based on a substrate 202, define active regions of access transistors of the 1T1C memory cells.

Step 20: Form underground bit lines connecting to the access transistors.

Step 25: Form word lines connecting to the access transistors and gates of the access transistors.

Step 30: Define memory cells isolation with drain regions (i.e. first conductive regions) and source regions (i.e. second conductive regions) of the access transistors of the 1T1C memory cells.

Step 35: Form connections between underground bit lines and the drain regions of the access transistors.

Step 40: Form the H-shape capacitors over the access transistors with connections to source regions of the access transistors.

Step 45: End.

Please refer to FIG. 1B and FIG. 2. Step 15 could include:

Step 102: Deposit a pad-oxide layer 204 and a pad-nitride layer 206 over a horizontal silicon surface (hereinafter, “HSS”) 208 of the substrate 202 (FIG. 2).

Step 104: Define the active regions of the 1T1C memory cells to create trench 210 (FIG. 2).

Step 106: Deposit an oxide layer (e.g. Silicon Oxide (SiO, SiO₂)) in the trench 210 and etched back the oxide layer 214 to form the shallow trench isolation (STI) below the horizontal silicon surface 208 (FIG. 2).

Please refer to FIG. 1C and FIG. 3, FIG. 4, FIG. 5. Step 20 could include:

Step 108: A nitride-1 layer (e.g. SiN or SiOCN) is deposited and etched back to form nitride-1 spacer 402 (e.g. SiN or SiOCN) (FIG. 3).

Step 110: A spin-on dielectrics (SOD) 404 is deposited in the trench 210 and planarized by chemical mechanical polishing (CMP) technique (FIG. 3).

Step 112: The nitride-1 spacer 402 (e.g. SiN or SiOCN) and the SOD 404 not covered by a photoresist layer are etched away (FIG. 3).

Step 114: The photoresist layer and the SOD 404 are stripped off (FIG. 4).

Step 116: An oxide-1 layer 502 is grown, such as thermal growth (FIG. 4).

Step 118: A conductive material 504 is deposited in the trench 210 and planarized by the CMP technique (FIG. 4).

Step 120: The conductive material 504 is etched back (FIG. 5).

Step 122: SiN 602 and oxide are deposited in the trench 210 and etched back, HDP (high-density-plasma) Oxide 604 is formed and planarized by the CMP technique, and then the HDP Oxide 604 is etched back and the pad-nitride layer 206 is etched away (FIG. 5).

Please refer to FIG. 1D and FIG. 6, FIG. 7, FIG. 8. Step 25 could include:

Step 124: An oxide-2 layer 702 and a nitride-2 layer 704 are deposited over a top of the pad-oxide layer 204 (FIG. 6).

Step 126: A patterned photoresist layer is deposited, and then unnecessary parts of the oxide-2 layer 702, the nitride-2 layer 704, the pad-oxide layer 204, and silicon are etched or removed (FIG. 7).

Step 128: A p-type selective epitaxy growth (p-SEG) 802 is grown, then an insulator layer 804 is formed, and then a gate material 806 is deposited and etched back to form the word lines and the gate structures of the access transistors (FIG. 7).

Step 130: A nitride layer 901, a nitride-3 layer 902 (e.g. SiN or SiOCN), and a nitride-4 layer 904 are deposited and planarized by the CMP technique, and the oxide-2 layer 702 and the nitride-2 layer 704 between the word lines are removed (FIG. 8).

Please refer to FIG. 1E and FIG. 9, FIG. 10, FIG. 11. Step 30 could include:

Step 132: A SiN layer 1002 and a polysilicon-1 layer 1004 are deposited and anisotropic etched back, and a spin-on dielectrics (SOD) 1006 is deposited and planarized by the CMP technique (FIG. 9).

Step 134: The polysilicon-1 layer 1004 is etched back and a nitride-5 layer 1008 is deposited and planarized by the CMP technique (FIG. 9).

Step 136: The spin-on dielectrics (SOD) 1006 is etched away, a nitride-6 layer 1102 is deposited, and a spin-on dielectrics (SOD) 1104 is deposited and planarized by the CMP technique (FIG. 10).

Step 138: A nitride-7 layer 1202 is deposited, and a photo pattern for source isolation is utilized to let the nitride-7 layer 1202, the spin-on dielectrics (SOD) 1104, the nitride-6 layer 1102, the pad-oxide layer 204, and the substrate 202 be etched to form an isolation trench inside the substrate 202 (FIG. 11).

Step 140: A spin-on dielectrics (SOD) 1204 is deposited to fill the isolation trench (FIG. 11).

Please refer to FIG. 1F and FIG. 12, FIG. 13, FIG. 14, FIG. 15. Step 35 could include:

Step 142: A photo pattern for UGBL contact is utilized to let the nitride-7 layer 1202, the spin-on dielectrics (SOD) 1104, the nitride-6 layer 1102, the pad-oxide layer 204, and the substrate 202 be etched to form a UGBL contact trench inside the substrate 202 (FIG. 12).

Step 144: An oxide-6 layer 1302 is grown and the nitride-1 spacer 402 (e.g. SiN or SiOCN) along the one side of the trench 210 is etched away (FIG. 12).

Step 146: A conductive material 1402 is deposited in the UGBL contact trench, planarized by the CMP technique, and etched back (FIG. 13).

Step 148: The oxide-6 layer 1302 is etched back and an n+ silicon layer 1404 is grown laterally based on the revealed silicon material to contact the drain region and the UGBL contact (FIG. 13).

Step 150: An oxide-7 layer 1502 is grown above the n+ silicon layer 1404, the nitride-6 layer 1102 is etched away, and a polysilicon-2 layer 1504 is deposited above the oxide-7 layer 1502 and etched back (FIG. 14).

Step 152: The nitride-7 layer 1202, the nitride-4 layer 904, the spin-on dielectrics (SOD) 1006, the nitride-5 layer 1008 are etched away (FIG. 15).

Step 154: A conductive material 1602 is deposited in the UGBL contact trench, planarized by the CMP technique, and etched back (FIG.

Please refer to FIG. 1G, FIG. 1H and FIG. 16, FIG. 17, FIG. 18, FIG. 19, FIG. 20, FIG. 21, FIG. 22, FIG. 23, FIG. 24, FIG. 25, FIG. 26, FIG. 27, FIG. 28. Step 40 could include:

Step 156: The polysilicon-1 layer 1004 and the pad-oxide layer 204 are etched away (FIG. 16).

Step 158: An n− SEG silicon 1702 is grown (FIG. 16).

Step 160: An oxide-8 layer 1902 is grown and etched back, an n+ SEG silicon 1904 is grown, and an oxide-9 layer 1906 is deposited and etched back (FIG. 18).

Step 162: The SiN layer 1002 is etched back, the n+ SEG silicon 1904 can be laterally grown, the oxide-9 layer 1906 is etched back, and an oxide-10 layer 2004 is grown above the n+ SEG silicon 1904 (FIG. 19).

Step 164: The conductive material 1602 is etched away, a nitride-8 layer 2102 is deposited and etched back, and the polysilicon-2 layer 1504 and the n− SEG silicon 1702 are etched away (FIG. 20).

Step 166: An oxide-11 layer 2202 is grown, the nitride-8 layer 2102 is removed, and a spin-on dielectrics (SOD) 2204 is deposited (FIG. 21).

Step 168: The spin-on dielectrics (SOD) 2204 is etched back, a Hi-K dielectric layer 2302, TiN layer 2304, and W layer 2306 are deposited and planarized by the chemical mechanical polishing (CMP) technique, the nitride-3 layer 902 (e.g. SiN or SiOCN) is etched back, and let the n+ SEG silicon is grown (FIG. 22).

Step 170: A nitride-9 layer 2402 is deposited, the nitride-9 layer 2402, the Hi-K dielectric layer 2302, the TiN layer 2304, and the W layer 2306 are planarized by the chemical mechanical polishing (CMP) technique, and let the n+ SEG silicons grown (FIG. 23).

Step 172: An oxide-12 layer 2502 is grown and etched back, the nitride-9 layer 2402 is etched away, and let the n+ SEG silicons vertically and laterally grown (FIG. 24).

Step 174: The oxide-12 layer 2502 and the Hi-K dielectric layer 2302 is etched away, a Hi-K dielectric layer 2602 is deposited and TiN layer 2604 is deposited, and a B-poly (Boron doped polysilicon) layer 2606 is deposited (FIG. 25).

Step 176: Parts of the Hi-K dielectric layer 2602, the TiN layer 2604, and the B-poly layer 2606 are removed by the chemical mechanical polishing (CMP) technique, the n+ SEG silicons are vertically grown from the two top heads 2506, a Hi-K dielectric layer 2702 is deposited, and a photoresist layer 2704 is formed above the Hi-K dielectric layer 2702 (FIG. 26).

Step 178: The Hi-K dielectric layer 2702 is etched, the photoresist layer 2704 is removed, TiN layer 2802 and a B-poly layer 2804 are deposited, and parts of the Hi-K dielectric layer 2702, the TiN layer 2802, and the B-poly layer 2804 are removed by the chemical mechanical polishing (CMP) technique (FIG. 27).

Step 180: Repeat Step 176, and Step 178 to form the multi-layers 2902 of the H-capacitor, and W layer 2904 is deposited (FIG. 28).

Detailed description of the aforesaid manufacturing method is as follows. Start with the substrate 202 (such as, a p-type silicon substrate). In Step 102, as shown in FIG. 2, the pad-oxide layer 204 is formed above the horizontal silicon surface (or original silicon surface (OSS)) 208 if the substrate 202 is silicon substrate, hereinafter the horizontal silicon surface or HSS is used as example. Then, the pad-nitride layer 206 (e.g. a SiN layer) is deposited above the pad-oxide layer 204.

In Step 104, as shown in FIG. 2(a), the active regions of the 1T1C memory cells can be defined by a photolithographic mask technique, so as shown in FIG. 2(a), the pad-oxide layer 204, the pad-nitride layer 206, and the horizontal silicon surface 208 outside the active regions can be etched by an anisotropic etching technique to create the trench (or canals) 210. In addition, FIG. 2(a) includes two cross-sectional drawings (“A-A” and “B-B”) that are taken where indicated in FIG. 2(b).

In Step 106, the oxide layer is deposited to fully fill the trench 210 and then the oxide layer is etched back such that the STI inside the trench 210 is formed below the HSS for hereafter underground bit line (UGBL) formation process later. In addition, as shown in FIG. 2(a), for example, the STI has a thickness about 140 nm and a top of the STI is about 110 nm deep below the HSS if the trench 210 is 250 nm deep below the HSS.

FIG. 3, FIG. 4 show the process to form two kinds of sidewall spacer between UGBL and the active region for getting different etching selectivity to meet UGBL to the active region contact formation requirement.

In Step 108, as shown in FIG. 3, the nitride-1 layer (e.g. SiOCN) is deposited and etched back by the anisotropic etching so as to create the nitride-1 spacer 402 (e.g. SiN or SiOCN) along both sides of the trench 210, wherein as shown in FIG. 3, for example, a thickness of the nitride-1 spacer 402 (e.g. SiN or SiOCN) is about 6 nm.

In Step 110, as shown in FIG. 3, the SOD 404 is deposited in the trench 210 above the STI to fill the trench 210. Then, the SOD 404 is planarized by the CMP technique for getting global planarization to make a top of the SOD 404 as high as a top of the pad-nitride layer 206.

In Step 112, as shown in FIG. 3, the nitride-1 spacer 402 (e.g. SiN or SiOCN) along one side of the trench 210 are protected by utilizing the photolithographic mask technique through the photoresist layer, but the nitride-1 spacer 402 (e.g. SiN or SiOCN) along the other side of the trench 210 are unprotected. That is, after the photoresist layer is deposited above the SOD 404 and the pad-nitride layer 206, because a part of the photoresist layer above the other side of the trench 210 is removed but a part of the photoresist layer above the one side of the trench 210 is kept, the nitride-1 spacer 402 (e.g. SiN or SiOCN) along one side of the trench 210 can be protected and the nitride-1 spacer 402 (e.g. SiN or SiOCN) along the other side of the trench 210 can be etched away.

In Step 114, as shown in FIG. 4, both the photoresist layer and the SOD 404 are stripped off to keep the nitride-1 spacer 402 (e.g. SiN or SiOCN) along one side of the trench 210 only, wherein the SOD 404 has much higher etching rate than that of thermal oxide and some deposited oxide.

Then, in Step 116, as shown in FIG. 4, the oxide-1 layer is grown thermally to form oxide-1 spacer 502 to cover the other side of the trench 210, wherein the oxide-1 spacer 502 is not grown over the pad-nitride layer 206. As shown in FIG. 4, Step 116 results in asymmetric spacers (the nitride-1 spacer 402 (e.g. SiN or SiOCN) and the oxide-1 spacer 502) on two symmetrical sides (the one side and the other side) of the trench 210, respectively. In addition, as shown in FIG. 4, for example, a thickness of the oxide-1 spacer 502 is also about 6 nm.

Then, in Step 118, as shown in FIG. 4, the conductive material 504 (e.g. composed of TiN layer 5042 and W layer 5044) is deposited in the trench 210 and then planarized by the CMP technique as UGBL material.

Then, in Step 120, as shown in FIG. 5, the conductive material 504 is etched back to keep required thickness for meeting UGBL resistance and parasitic capacitance requirement that can be done by good dry etching rate control.

Then, in Step 122, as shown in FIG. 5, the SiN 602 and the oxide are deposited in the trench 210 and etched back, then the HDP Oxide 604 is formed and planarized by the CMP technique, and then the HDP Oxide 604 is etched back and the pad-nitride layer 206 is etched away to let the pad-oxide layer 204 remain on a top of the HSS with flat surface.

Then, in Step 124, as shown in FIG. 6, the oxide-2 layer 702 (e.g. SiO₂) and the nitride-2 layer 704 (e.g. SiN) are deposited over the top of the pad-oxide layer 204 for following buried-WL (word line) formation process, wherein for example, a thickness of the oxide-2 layer 702 is about 10 nm, a thickness of the nitride-2 layer 704 is about 45 nm, and a thickness of the pad-oxide layer 204 is about 5 nm.

Then, in Step 126, as shown in FIG. 7, first, the patterned photoresist layer is deposited. Then, the unnecessary parts of the oxide-2 layer 702, the nitride-2 layer 704, the pad-oxide layer 204, and silicon are etched are removed by using etching technique. A transistor/word line pattern will be defined by the composite layers of the oxide-2 layer 702 and the nitride-2 layer 704, wherein the composite layers of the oxide-2 layer 702 and the nitride-2 layer 704 consists of multiple stripes in a direction perpendicular to a direction of the active region. Therefore, as shown in FIG. 7, longitudinal (the Y direction (i.e. view A-A shown in FIG. 2(b))) stripes (the oxide-2 layer 702 and the nitride-2 layer 704) for defining the access transistors and buried-WL formation are formed, wherein the active region is located at cross-point square between the longitudinal stripes. In addition, as shown in FIG. 7, the unnecessary parts of silicon are etched to create a U-shaped concave (e.g. about 50 nm deep).

Then, in Step 128, as shown in FIG. 7, first, the p-SEG 802 (e.g. about 3 nm thickness) is grown on a surface of the U-shaped concave as a channel layer of the access transistors, wherein the channel layer can have tight dopant concentration control for getting good cell access transistor characteristics. Then, as shown in FIG. 7, the insulator layer 804 (e.g. about 2 nm thickness thin oxide) is formed. Then, as shown in FIG. 7, the gate material (e.g. composed of TiN layer 8062 and W layer 8064) 806 is deposited with CMP and then etched back to form the word lines and the gate structures of the access transistors.

Then, in Step 130, as shown in FIG. 8, the thin nitride layer 901 (e.g. SiN), the nitride-3 layer 902 (e.g. SiN or SiOCN), and the nitride-4 layer 904 (e.g. SiN) are deposited and planarized by the CMP technique to fill the gap to form protection on the top of the word lines (i.e. the buried-WLs). Then, the oxide-2 layer 702 and the nitride-2 layer 704 between the word lines are removed.

Then, in Step 132, as shown in FIG. 9, the SiN layer 1002 (e.g. SiO₂) is deposited and anisotropic etched back and the polysilicon-1 layer 1004 is deposited and anisotropic etched back to form sidewall spacers for the word lines. In addition, as shown in FIG. 9, the spin-on dielectrics (SOD) 1006 is deposited and planarized by the CMP technique to fill all the gaps and achieve planarization.

Then, in Step 134, as shown in FIG. 9, the polysilicon-1 layer 1004 is etched back by dry etching process that can have good control for forming polysilicon recess, and then the nitride-5 layer 1008 is deposited into the polysilicon recess and planarized by the CMP technique to be leveled as high as to a top of the nitride-4 layer 904 to act as polysilicon spacer protection layer.

Then, in Step 136, as shown in FIG. 10, the spin-on dielectrics (SOD) 1006 is etched away, then the nitride-6 layer 1102 (e.g. SiN) is deposited as bottom protection film, and then the spin-on dielectrics (SOD) 1104 is deposited to fill all gaps and planarized by the CMP technique.

Then, in Step 138, as shown in FIG. 11, the nitride-7 layer 1202 (e.g. SiN) is deposited on all top, and then the photo pattern for source isolation is utilized and the dry etching process with good etching rate control is applied to etch the nitride-7 layer 1202, the spin-on dielectrics (SOD) 1104, the nitride-6 layer 1102, the pad-oxide layer 204, and the substrate 202 to form the isolation trench inside the substrate 202.

Then, in Step 140, as shown in FIG. 11, the spin-on dielectrics (SOD) 1204 is deposited into the isolation trench for formation of the source isolation of the access transistors.

Then, in Step 142, as shown in FIG. 12(a), the photo pattern for UGBL contact is utilized and the dry etching process with good etching rate control is applied to etch the nitride-7 layer 1202, the spin-on dielectrics (SOD) 1104, the nitride-6 layer 1102, the pad-oxide layer 204, and the substrate 202 to form the UGBL contact trench inside the substrate 202. In addition, FIG. 12(a) includes two cross-sectional drawings (“C-C” and “D-D”) that are taken where indicated in FIG. 12(b).

Then, in Step 144, as shown in FIG. 12(a), the oxide-6 layer 1302 (e.g. SiO₂) is thermally grown on the UGBL contact trench and the nitride-1 spacer 402 (e.g. SiN or SiOCN) along the one side of the trench 210 is etched away by the dry etching process to expose the conductive material 504 (e.g. composed of TiN layer 5042 and W layer 5044) for UGBL contact connection.

Then, in Step 146, as shown in FIG. 13(a), the conductive material 1402 (e.g. composed of TiN layer 14022 and W layer 14024) is deposited in the UGBL contact trench, planarized by the CMP technique, and etched back to form the UGBL contact which is good connection with the UGBL, wherein the oxide-6 layer 1302 is used for protecting the UGBL contact and separating the UGBL contact from the substrate 202. In addition, as shown in FIG. 13(a), a top of the conductive material 1402 needs to be kept near the HSS for the drain region connection of the access transistor.

In addition, combining FIG. 3 and FIG. 12 can understand that two sides of the UGBL contact are covered by the oxide-6 layer 1302, one side of the UGBL contact is covered by the oxide-1 spacer 502, and the last one side of the UGBL contact is covered by the nitride-1 spacer 402 (e.g. SiN or SiOCN), so it is very clear that the nitride-1 spacer 402 (e.g. SiN or SiOCN) is located between the UGBL (i.e. the conductive material 504) and the UGBL contact (i.e. the conductive material 1402). That is, that the nitride-1 spacer 402 (e.g. SiN or SiOCN) along the one side of the trench 210 is etched away can expose the conductive material 504 (e.g. composed of TiN layer 5042 and W layer 5044) for UGBL contact connection.

Then, in Step 148, as shown in FIG. 13(a), the oxide-6 layer 1302 (e.g. SiO₂) on a top of the UBGL contact is etched back to reveal silicon material and then the n+ silicon layer 1404 is grown laterally by the selective epitaxy growth technique based on the revealed silicon material, wherein the n+ silicon layer 1404 will perform a good connection from the UGBL contact to the drain region of the access transistor. In addition, FIG. 13(b) is a magnified view of the black dotted rectangle shown in FIG. 13(a).

Then, in Step 150, as shown in FIG. 14(a), the oxide-7 layer 1502 is thermally grown above the n+ silicon layer 1404 to form n+ SEG protection, then the nitride-6 layer 1102 is etched away, and the polysilicon-2 layer 1504 is deposited above the oxide-7 layer 1502 and etched back to remain polysilicon on a top of the n+ silicon layer 1404 as following dielectric remove protection. In addition, FIG. 14(b) is a magnified view of the black dotted rectangle shown in FIG. 14(a).

Then, in Step 152, as shown in FIG. 15(a), the nitride-7 layer 1202, the nitride-4 layer 904, the spin-on dielectrics (SOD) 1006, the nitride-5 layer 1008 are etched away to make sidewall of the polysilicon-1 layer 1004 exposed.

Then, in Step 154, as shown in FIG. 15(a), the conductive material 1602 (e.g. composed of TiN layer 16022 and W layer 16024) is deposited to fill the gap, planarized by the CMP technique, and etched back to act as protection layer.

Then, in Step 156 and Step 158, as shown in FIG. 16(a), the polysilicon-1 layer 1004 and the pad-oxide layer 204 are etched away and the n− SEG silicon 1702 is grown from the HSS by the selective epitaxial growth (SEG) technique. In addition, FIG. 16(a) includes two cross-sectional drawings (“E-E” and “F-F”) that are taken where indicated in FIG. 16(b). In addition, FIG. 17 shows magnified views of the black dotted rectangles shown in FIG. 16(a).

Then, in Step 160, as shown in FIG. 18, the oxide-8 layer 1902 is thermally grown and etched back to keep sidewall of the n− SEG silicon 1702 and expose a top surface of the n− SEG silicon 1702 for following SEG silicon vertical growth process. Then, the n+ SEG silicon 1904 (e.g. 12 nm) is grown by the selective epitaxial growth (SEG) technique based on the top surface of the n− SEG silicon 1702. Then, the oxide-9 layer 1906 (e.g. SiO₂) is deposited and etched back to form protection on a top of the n+ SEG silicon 1904 and expose out the SiN layer 1002 (which is sidewall spacers for the word lines). In addition, FIG. 18 shows the key process steps to continuous SEG silicon growth vertically and corresponds to FIG. 17.

Then, in Step 162, as shown in FIG. 19(a), the SiN layer 1002 is etched back, and then the n+ SEG silicon 1904 is laterally grown by the selective epitaxial growth (SEG) technique to extend foots of the H-capacitor to get larger area for H-capacitors of the 1T1C memory cells. And then, the oxide-9 layer 1906 is etched back to reveal a top of the n+ SEG silicon 1904 so that the oxide-10 layer 2004 is thermally grown above the n+ SEG silicon 1904 to form oxidation protection for the n+ SEG silicon 1904. In addition, FIG. 19(b) is a magnified view of the black dotted rectangle shown in FIG. 19(a). In addition, FIG. 19(a) includes two cross-sectional drawings (“E-E” and “F-F”) that are taken where indicated in FIG. 16(b).

In addition, in another embodiment of the present invention, in Step 160, as shown in FIG. 18A, the oxide-8 layer 1902 is thermally grown and etched back to keep sidewall of the n− SEG silicon 1702 and expose a top surface of the n− SEG silicon 1702 for following SEG silicon vertical growth process. Then, the n+ SEG silicon 1904 (e.g. 2.5 nm) is grown by the selective epitaxial growth (SEG) technique based on the top surface of the n− SEG silicon 1702. Then, the oxide-9 layer 1906 (e.g. SiO₂) is deposited and etched back to form protection on a top of the n+ SEG silicon 1904 and expose out the SiN layer 1002 (which is sidewall spacers for the word lines). Then, the SiN layer 1002 is etched back.

In another embodiment of the present invention, in Step 162, as shown in FIG. 19A, the n+ SEG silicon 1904 is laterally grown by the selective epitaxial growth (SEG) technique to extend foots of the H-capacitor to get larger area for H-capacitors of the 1T1C memory cells. And then, the oxide-9 layer 1906 is etched back to reveal a top of the n+ SEG silicon 1904 so that the n+ SEG silicon 1904 can be continuously laterally and vertically grown by the selective epitaxial growth (SEG) technique to further extend foots of the H-capacitor. Then, the oxide-10 layer 2004 is thermally grown above the n+ SEG silicon 1904 to form oxidation protection for the n+ SEG silicon 1904. In addition, FIG. 19A also includes two cross-sectional drawings (“E-E” and “F-F”) that are taken where indicated in FIG. 16(b).

Then, in Step 164, as shown in FIG. 20(a), the conductive material 1602 is etched away, then the nitride-8 layer 2102 (e.g. SiN) is deposited and etched back to form SiN sidewall spacer protection, and then the polysilicon-2 layer 1504 (only at the drain region of the access transistor) is removed. Then, perform poly wet etching process that can etching through and remove the n− SEG silicon 1702 at the drain region of the access transistor. In addition, FIG. 19(b) is a magnified view of the black dotted rectangle shown in FIG. 19(a).

Then, in Step 166, as shown in FIG. 21, apply thermal oxidation that will oxidize all of bottoms of SEG silicons (i.e. the n+ SEG silicon 1904) to grow the oxide-11 layer 2202 in a bottom of the drain region of the access transistor to form good separation between H-capacitor and the assess transistor. In addition, the nitride-8 layer 2102 is removed and spin-on dielectrics (SOD) 2204 is deposited and planarized by chemical mechanical polishing (CMP) technique. In addition, FIG. 19, FIG. 20, FIG. 21 shows the process to cut off the connection between the H-capacitor and the drain region of the access transistor for good separation and to keep good connection between the H-capacitor and the source region of the access transistor.

Then, in Step 168, as shown in FIG. 22(a), the spin-on dielectrics (SOD) 2204 is etched back, and the Hi-K dielectric layer 2302, TiN layer 2304, and W layer 2306 are deposited and planarized by chemical mechanical polishing (CMP) technique to form protection on a top of the n+ SEG silicons (i.e. the n+ SEG silicon 1904) and expose the nitride-3 layer 902 (e.g. SiN or SiOCN). Then, the nitride-3 layer 902 (e.g. SiN or SiOCN) is etched back to let the n+ SEG silicons is laterally grown as initial state for H-capacitor clamping on the access transistor based on the n+ SEG silicons.

Then, in Step 170, as shown in FIG. 23, first the nitride-9 layer 2402 (e.g. SiN) is deposited, and then the nitride-9 layer 2402, the Hi-K dielectric layer 2302, TiN layer 2304, and W layer 2306 are planarized by chemical mechanical polishing (CMP) technique to let the nitride-9 layer 2402 remain in between of two n+ SEG silicons and also expose tops of the two n+ SEG silicons by using the Hi-K dielectric layer 2302 to cover the other areas. Then, the exposed n+ SEG silicons are vertically grown. In addition, FIG. 23(b) is a top view corresponding to FIG. 23(a). In addition, FIG. 23(a) includes two cross-sectional drawings (“G-G” and “H-H”) that are taken where indicated in FIG. 23(b). In addition, FIG. 18, FIG. 19, FIG. 20, FIG. 21, FIG. 22, FIG. 23 show the process form the foots of the H-capacitor with good connection with the access transistor.

Then, in Step 172, as shown in FIG. 24 (a), first the oxide-12 layer 2502 is thermally grown and etched back, and then the nitride-9 layer 2402 is etched away by the wet etching technique. Then, as shown in FIG. 24, the n+ SEG silicons are grown from exposed sidewall and top side (that is, the n+ SEG silicons are grown vertically and laterally), wherein the oxide-12 layer 2502 can be a guide to keep the n+ SEG silicons vertically grown. Thus, the n+ SEG silicons will grow a horizontal line 2504 and two top heads 2506 for the H-capacitor clamp on the assess transistor. In addition, FIG. 24(b) is a magnified view of the black dotted rectangle shown in FIG. 24(a).

Then, in Step 174, as shown in FIG. 25(a), first the oxide-12 layer 2502 is etched away. Then, the Hi-K dielectric layer 2602 is deposited and etched back to get clean surface for a bottom plate of the H-capacitor, and then re-deposit High-K dielectric for the H-capacitor formation. Then, as shown in FIG. 25(a), the TiN layer 2604 and the B-poly layer 2606 are deposited as top plate. Therefore, a first layer of the H-capacitor is completely. In addition, FIG. is a magnified view of the black dotted rectangle shown in FIG.

Then, in Step 176, as shown in FIG. 26, first the parts of the Hi-K dielectric layer 2602, the TiN layer 2604, and the B-poly layer 2606 are removed by the chemical mechanical polishing (CMP) technique to expose tops of the n+ SEG silicons for following formation of multi-layers of the H-capacitor. As shown in FIG. 26, the n+ SEG silicons are vertically grown from the two top heads 2506 to extend the bottom plate of the H-capacitor. In addition, the Hi-K dielectric layer 2702 is deposited and the photoresist layer 2704 is formed above the Hi-K dielectric layer 2702 to protect cell array area.

Then, in Step 178, as shown in FIG. 27, the Hi-K dielectric layer 2702 is etched at cell array boundary area for following top plate of B-poly layer (i.e. the B-poly layer 2606 and the B-poly layer 2804)/TiN layer (i.e. the TiN layer 2604 and the TiN layer 2802) connection. Parts of the Hi-K dielectric layer 2702, the TiN layer 2802, and the B-poly layer 2804 are removed by the chemical mechanical polishing (CMP) technique to expose tops of the n+ SEG silicons for following formation of multi-layers of the H-capacitor. By using the same process from FIG. 26, FIG. 27 that can continuous stacking the H-capacitor until meet capacitance requirement.

Then, in Step 180, as shown in FIG. 28, the W layer 2904 is deposited on a top of the top plate of the H-capacitor to get lower sheet resistance which completes the H-capacitor process. FIG. 28 shows the final UGBL (underground bit line) and HCoT (H-capacitor clamping the access transistor) DRAM Cell Structure.

In addition, in another embodiment of the present invention, in Step 176, as shown in FIG. 26A, first the parts of the Hi-K dielectric layer 2602, the TiN layer 2604, and the B-poly layer 2606 are removed by the chemical mechanical polishing (CMP) technique to expose tops of the n+ SEG silicons for following formation of multi-layers of the H-capacitor. As shown in FIG. 26A, the n+ SEG polysilicons 2608 with rough surface (or Hemispherical-grained (HSG) Si) are vertically grown from the two top heads 2506 to get larger capacitance. In addition, the Hi-K dielectric layer 2702 is deposited and the photoresist layer 2704 is formed above the Hi-K dielectric layer 2702 to protect cell array area.

Then, in Step 178, as shown in FIG. 27A, the Hi-K dielectric layer 2702 is etched at cell array boundary area for following top plate of B-poly layer (i.e. the B-poly layer 2606 and the B-poly layer 2804)/TiN layer (i.e. the TiN layer 2604 and the TiN layer 2802) connection. Parts of the Hi-K dielectric layer 2702, the TiN layer 2802, and the B-poly layer 2804 are removed by the chemical mechanical polishing (CMP) technique to expose tops of the n+ SEG polysilicons 2608 (or the HSG Si) for following formation of multi-layers of the H-capacitor. That by using the same process from FIG. 26A, FIG. 27A can continuously stack the H-capacitor until meet capacitance requirement. That by applying rough surfaces of the n+ SEG polysilicons 2608 (or the HSG Si) can get larger capacitance by the same stack height, also can reduce the stack height if fitting to the same capacitance.

Then, in Step 180, as shown in FIG. 28A, the multi-layers 2902 of the H-capacitor is completed and the W layer 2904 is deposited on a top of the top plate of the H-capacitor to get lower sheet resistance which completes the H-capacitor process. FIG. 28A shows the final UGBL (underground bit line) and HCoT (H-capacitor clamping the access transistor) DRAM Cell Structure.

In addition, in another embodiment of the present invention, following in Step 178, as shown in FIG. 28B, show the process to start forming ladder connection after the H-capacitor stacking. The structure of H-capacitor of the 1T1C memory cells uses the n+ SEG silicon 1904 as bottom plate of the H-capacitor, uses the Hi-K dielectric layer 2602 as capacitor dielectric of the H-capacitor, and uses the B-poly layer 2606/the TiN layer 2604 as top plate of the H-capacitor which can repeat stacking as high as needs to meet capacitance requirement. By inserting additional processes as described in following FIG. 29, FIG. 30, FIG. 31, FIG. 32, FIG. 33, FIG. 34, FIG. 35 can form a ladder type H-capacitor to increase the H-capacitor surface area for reducing the H-capacitor stacking height.

Then, as shown in FIG. 29, perform the CMP technique to remove the Hi-K dielectric layer 2702, the TiN layer 2802, and the B-poly layer 2804 on tops of the n+ SEG silicons (i.e. the n+ SEG silicon 1904) for n+ SEG growth. Then, deposit SiN layer 2904 with CMP and etch back to form SiN remain between the n+ SEG silicons as block for ladder formation. As show in FIG. 29, there are three kinds of spacing between the n+ SEG silicons, spacing “A” is on a top of the bit line contact, spacing “B” is on a top of the source isolation, and spacing “C” is on a top of the access transistor that is the target to form the ladder connection.

Then, as shown in FIG. 30(a), deposit thin TiN layer 3002 to protect the SiN layer 2904 and the n+ SEG silicons, and then deposit SiO₂ layer with etch back to form SiO₂ sidewall spacer 3004. Then, deposit thin SiN layer 3006 to fill the small gap between the SiO₂ sidewall spacer 3004 in the spacing “C” which is located on the top of the access transistor but still keep small gap opening for the spacing “A” and the spacing “B” those on the top of the bit line Contact and on the top of the source isolation, respectively. Then, deposit polysilicon 3008 and CMP to fill the remaining gap in the spacing “A” and the spacing “B”. In addition, FIG. 30(b) is a magnified view of the black dotted rectangle shown in FIG. 30(a).

Then, as shown in FIG. 31(a), perform the isotropic etching on the thin SiN layer 3006 and do thermal oxidation to transfer partial of the polysilicon 3008 become oxide layer 3102 that will fill in the gap of the spacing “A” and the spacing “B” but not oxide in the spacing “C” due to no the polysilicon 3008 inside the spacing “C”. Then, perform the isotropic etching on the SiO₂ sidewall spacer 3004 inside the gap of the spacing “C”.

Then, as shown in FIG. 32(a), do Polysilicon partial etching and thermal oxidation to turn all of the remaining polysilicon 3008 become the oxide layer 3102 in the gap of the spacing “A” and the spacing “B” as cover film for the SiN layer 2904. Then, do TiN and SiN anisotropic dry etching to etch the thin TiN layer 3002 and the SiN layer 2904 in the spacing “C”.

Then, as shown in FIG. 33, do SiO₂ isotropic etching to etch away the oxide layer 3102 and the SiO₂ sidewall spacer 3004 in the spacing “A” and the spacing “B”, and do SiN isotropic etching to etch away the remaining SiN layer 2904 in the spacing “C” to open bottom sidewalls of the n+ SEG silicons in the spacing “C”. Then, the n+ SEG silicons are laterally and vertically grown so that ladder connections (on the top of the access transistor) at the spacing “C” are formed. Then, remove the remaining thin TiN layer 3002 and the remaining SiN layer 2904.

Then, as shown in FIG. 34, do the Hi-K dielectric layer and the top plate of B-poly layer/the TiN layer deposition again which can back to repeat process for H-capacitor stacking.

Then, as shown in FIG. 35, FIG. 35 shows the repeating stacking to perform ladder structure for the H-capacitor that can enhance the cell storage capacitor surface area for getting larger capacitance. In addition, as shown in FIG. 35, the W layer is deposited on a top of the top plate of the H-capacitor to get lower sheet resistance which completed the H-capacitor process. It shows the final UGBL (underground bit line) and HCoT (H-capacitor clamping the access transistor) DRAM Cell with multiple-ladders electrode Structure.

In addition, lengths shown in figures of the present invention are examples which used for describing the present invention, and not to limit the present invention.

In summary, the present invention presents a new architecture of DRAM cell which not only compacts the size of the DRAM cell but also enhances the signal-to-noise ratio during the DRAM cell operation. Since the H-capacitor is located over the access transistor and largely encompasses the access transistor as well as inventing both vertical and horizontal self-alignment techniques of arranging and connecting the geometries of these essential micro-structures in the DRAM Cell, the HCoT DRAM cell architecture can reserve the merit of at least 4 to 10 square units even when the minimum physical feature size is much less than 10 nanometers.

The bit line inside the substrate will provide lower parasitic capacitance for better cell signal sensing and totally self-aligned process to achieve cell isolation in smaller dimension with good connection to the H-capacitor. Moreover, the gate-induced drain leakage (GIDL) could also be reduced due to the well-designed transistor structure, and the combination of such reduced gate-induced drain leakage (GIDL) with the reduced leakage derived from the lower process temperature could further enlarge the signal-to-noise ratio and effectuate the possibility of using a much smaller size of the H-capacitor in the HCoT DRAM cell without negatively impacting the reliability of the stored data.

Additionally, the H-capacitor clamping on the access transistor can keep stacking by repeating the same process until meet cell capacitance requirement without the concern to have short with neighboring capacitor, no matter how high of the H-capacitor. In addition, through n+ SEG lateral growth that can maximize the electrode area of the H-capacitor to get larger capacitance of the H-capacitor for bigger signal storage. In addition, by combining n+ Poly or HSG selective growth that can further enhance the H-capacitor bottom electrode area to get larger capacitance of the H-capacitor for signal storage. In addition, through the Multiple-Ladders Electrode process which can get larger cell capacitor area to increase the cell capacitance for getting bigger storage signal. So, this DRAM cell with UGBL (underground bit line) and HCoT (H-capacitor clamping an access transistor) structure provided an excellent capability to continuous shrink for advance technology node.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A memory cell structure comprising:
a silicon substrate with a silicon surface;
a transistor coupled to the silicon surface, the transistor comprising a gate structure, a first conductive region, and a second conductive region; and
a capacitor with a signal electrode and a counter electrode, the capacitor being over the transistor, and the signal electrode electrically being coupled to the second conductive region of the transistor and isolated from the first conductive region of the transistor;
wherein the counter electrode comprises a plurality of sub-electrodes electrically connected with each other.

2. The memory cell structure of claim 1, wherein a dielectric layer is inserted between every two adjacent sub-electrodes.

3. The memory cell structure of claim 2, wherein each sub-electrode comprises a TiN layer and a boron doped polysilicon layer.

4. The memory cell structure of claim 1, wherein the signal electrode comprises Si.

5. The memory cell structure of claim 1, wherein the signal electrode has an H-shape structure covering a top surface and two sidewalls of the gate structure.

6. The memory cell structure of claim 1, wherein the signal electrode comprises two upward extending pillars and a plurality of lateral beams connected the two upward extending pillars.

7. The memory cell structure of claim 1, further comprising an active region in the silicon substrate and surrounded by a shallow trench isolation (STI) region, wherein the transistor is formed based on the active region, and the signal electrode comprises two upward extending pillars, at least one upward extending pillar laterally expands beyond the active region.

8. The memory cell structure of claim 7, wherein a bottom surface of each upward extending pillar covers the active region and the STI region.

9. The memory cell structure of claim 1, wherein the signal electrode comprises two upward extending pillars with rough surface.

10. The memory cell structure of claim 9, wherein the signal electrode comprises n+ Poly Si or Hemispherical-grained Si.

11. A memory cell structure comprising:
a semiconductor substrate with an original semiconductor surface;
an active region in the semiconductor substrate and surrounded by a shallow trench isolation (STI) region;
a transistor formed based on the active region, the transistor comprising a gate structure, a first conductive region, and a second conductive region; and
a capacitor with a signal electrode and a counter electrode, the capacitor being over the transistor, and the signal electrode electrically being coupled to the second conductive region of the transistor and isolated from the first conductive region of the transistor;
wherein the signal electrode comprises two upward extending pillars, and each upward extending pillar stacks over the active region and laterally expands beyond the active region.

12. The memory cell structure of claim 11, wherein the gate structure comprises a gate conductive region and a cap dielectric region above the gate conductive region, and a top surface of the gate conductive region is lower than the original semiconductor surface.

13. The memory cell structure of claim 11, wherein the counter electrode comprises a plurality of sub-electrodes electrically connected with each other, each sub-electrode comprises a TiN layer and a boron doped polysilicon layer, and the signal electrode comprises Si.

14. The memory cell structure of claim 11, wherein the signal electrode has an H-shape structure covering a top surface and two sidewalls of the gate structure.

15. The memory cell structure of claim 14, further comprising:
a bit line disposed under the original semiconductor surface; and
a connecting plug electrically connecting the bit line to the first conductive region of the transistor.

16. The memory cell structure of claim 15, wherein the bit line is disposed within the STI region, and the STI region comprises a set of asymmetric material spacers.

17. A memory cell structure comprising:
a semiconductor substrate with an original semiconductor surface;
an active region in the semiconductor substrate and surrounded by a shallow trench isolation (STI) region;
a transistor formed based on the active region, the transistor comprising a gate structure, a first conductive region, and a second conductive region; and
a capacitor with a signal electrode and a counter electrode, the signal electrode covering a top surface and two sidewalls of the gate structure, and the signal electrode electrically being coupled to the second conductive region of the transistor and isolated from the first conductive region of the transistor;
wherein the signal electrode comprises two upward extending pillars with rough surface, and each upward extending pillar comprises n+ Poly Si or Hemispherical-grained Si.

18. The memory cell structure of claim 17, wherein the counter electrode comprises a plurality of sub-electrodes electrically connected with each other, and a dielectric layer is inserted between every two adjacent sub-electrodes.

19. The memory cell structure of claim 18, wherein each sub-electrode comprises a TiN layer and a boron doped polysilicon layer.

20. The memory cell structure of claim 17, further comprising:
a bit line disposed under the original semiconductor surface; and
a connecting plug electrically connecting the bit line to the first conductive region of the transistor;
wherein the bit line is disposed within the STI region, and the STI region comprises a set of asymmetric material spacers.
